(19) United States
(12) Patent Application Publication
(10) Pub. No.: US 2026/0096338 A1
(43) Pub. Date: Apr. 2, 2026

(54) METAL OXIDE NANOPARTICLE COMPOSITION, AND LIGHT-EMITTING DEVICE, ELECTRONIC DEVICE AND ELECTRONIC APPARATUS, INCLUDING THE SAME

(71) Applicant: Samsung Display Co., LTD., Yongin-si (KR)

(72) Inventors: Chulsoon Park, Yongin-si (KR); Byounghun Sung, Yongin-si (KR); Doohyun Lee, Yongin-si (KR)

(21) Appl. No.: 19/333,229

(22) Filed: Sep. 18, 2025

(30) Foreign Application Priority Data
Sep. 27, 2024 (KR) 10-2024-0132002

(51) Int. Cl. H10K 85/10; B82Y 20/00; C08K 3/30; C09K 11/88; H10K 50/165; H10K 102/00

(52) U.S. Cl. CPC H10K 85/141; C08K 3/30; C09K 11/883; B82Y 20/00; C08K 2201/011; H10K 50/165; H10K 2102/351

(57) ABSTRACT

Provided is a metal oxide nanoparticle composition including metal oxide nanoparticles, a polymer including a moiety represented by Formula 1, and a solvent, wherein an amount of the polymer is about 0.1 wt % to about 1 wt % of the weight of the metal oxide nanoparticles, wherein, in Formula 1, R₁ is a functional group including two or more electron donor atoms, and n is an integer from 100 to 500:

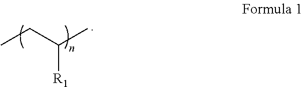

### CROSS-REFERENCE TO RELATED APPLICATION

The present application claims priority to and the benefit of Korean Patent Application No. 10-2024-0132002, filed on Sep. 27, 2024, in the Korean Intellectual Property Office, the entire content of which is hereby incorporated by reference.

### BACKGROUND

### 1. Field

One or more embodiments of the present disclosure relate to a metal oxide nanoparticle composition, and a light-emitting device, an electronic device and an electronic apparatus, including the same.

### 2. Description of the Related Art

Self-emissive devices among light-emitting devices have wide viewing angles, high contrast ratios, short response times, and excellent characteristics in terms of luminance, driving voltage, and response speed.

In a light-emitting device, a first electrode is on a substrate, and a hole transport region, an emission layer, an electron transport region, and a second electrode are sequentially on the first electrode. Holes provided from the first electrode move toward the emission layer through the hole transport region, and electrons provided from the second electrode move toward the emission layer through the electron transport region. Carriers, such as holes and electrons, recombine in the emission layer to produce excitons. The excitons transition from an excited state to a ground state, thereby generating light.

### SUMMARY

One or more embodiments of the present disclosure include a metal oxide nanoparticle composition to form a light-emitting device having improved efficiency and a light-emitting device formed therefrom.

Additional aspects of embodiments will be set forth in part in the description which follows and, in part, will be apparent from the description, or may be learned by practice of the presented embodiments of the disclosure.

According to one or more embodiments, a metal oxide nanoparticle composition includes:
metal oxide nanoparticles,
a polymer including a moiety represented by Formula 1, and
a solvent,
wherein an amount of the polymer is about 0.1 wt % to about 1 wt % of a weight of the metal oxide nanoparticles:

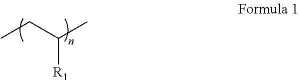

wherein, in Formula 1, R₁ is a functional group including two or more electron donor atoms, and n is an integer from 100 to 500.

According to one or more embodiments, a light-emitting device includes:
an anode,
a cathode facing the anode, and
an interlayer including an emission layer and an electron transport, wherein the emission layer is between the anode and the cathode and the electron transport region is between the emission layer and the cathode,
wherein the electron transport region includes metal oxide nanoparticles, and
a polymer including a moiety represented by Formula 1,
wherein an amount of the polymer is about 0.1 wt % to about 1 wt % of a weight of the metal oxide nanoparticles.

According to one or more embodiments, an electronic device includes the light-emitting device.

According to one or more embodiments, an electronic apparatus includes the light-emitting device.

### BRIEF DESCRIPTION OF THE DRAWINGS

The above and other aspects and features of certain embodiments of the disclosure will be more apparent from the following description taken in conjunction with the accompanying drawings, in which:

FIG. 1 a schematic cross-sectional view of a light-emitting device according to an embodiment;

FIG. 2 a schematic cross-sectional view of an electronic device according to an embodiment;

FIG. 3 shows a schematic cross-sectional view of an electronic device according to an embodiment;

FIGS. 4 and 5 are schematic perspective views of embodiments of an electronic apparatus; and

FIGS. 6A, 6B, and 6C are each a schematic interior view of an electronic apparatus according to embodiments of the present disclosure.

### DETAILED DESCRIPTION

Reference will now be made in more detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of embodiments of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Because the subject matter of the present disclosure may have diverse modified embodiments, embodiments are illustrated in the drawings and are described in the detailed description. An effect and a characteristic of the disclosure, and a method of accomplishing these will be apparent when referring to embodiments described with reference to the drawings. The subject matter of the present disclosure may, however, be embodied in many different forms and should not be construed as being limited to the embodiments set forth herein.

It will be understood that although the terms “first,” “second,” etc. used herein may be used herein to describe various components, these components should not be limited by these terms. These terms are only used to distinguish one component from another.

An expression used in the singular encompasses the expression of the plural, unless it has a clearly different meaning in the context.

It will be further understood that the terms “include” and/or “have” used herein specify the presence of stated features or components, but do not preclude the presence or addition of one or more other features or components. Unless defined otherwise, the terms “include” and/or “have” may refer to both the case of consisting of features or components described in the specification and the case of further including other components.

### Metal Oxide Nanoparticle Composition

A metal oxide nanoparticle composition according to an embodiment includes:
metal oxide nanoparticles;
a polymer including a moiety represented by Formula 1; and a solvent:

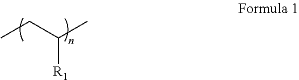

wherein, in Formula 1, R₁ is a functional group including two or more electron donor atoms, and n is an integer from 100 to 500. An amount of the polymer may be about 0.1 wt % to about 1 wt % of a weight of the metal oxide nanoparticles.

According to an embodiment, the polymer may further include a functional group such as a carbonyl group, a hydroxyl group, an amine group, an amide group, and/or the like in a backbone including or consisting of carbon chains.

The electron donor atoms may include nitrogen (N) or oxygen (O).

The functional groups R₁ may each independently include one of Structures 1 to 4 below:

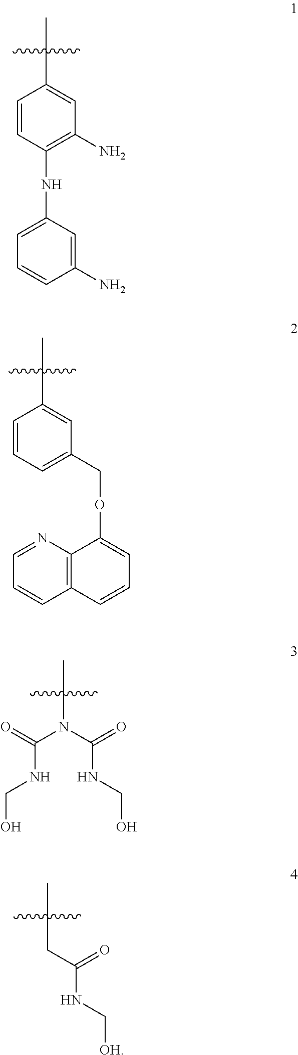 [SMILES: *c1ccc(Nc2cccc(N)c2)c(N)c1 ; *c1cccc(COc2cccc3cccnc23)c1 ; *N(C(=O)NCO)C(=O)NCO ; *CC(=O)NCO]

The polymer may have, for example, a weight average molecular weight (Mw) of about 10,000 to about 50,000.

The metal oxide nanoparticles may include, but are not limited to, ZnO, ZnMgO, ZnMgO:Sn, ZnSnO, ZnAlO, SnO₂, TiO₂, or any combination thereof. The metal oxide nanoparticles may be selected from among suitable metal oxides having electron transport capability.

According to an embodiment, a diameter of the metal oxide nanoparticle may be, for example, about 3 nm to about 5 nm. According to an embodiment, the metal oxide nanoparticle may include a ligand on the surface thereof. For example, the ligand may include a thiol group, a carboxyl group, an amino group, a catechol group, an amide group, a thioacetic acid group, and/or the like as an anchoring group, and may include ethylene glycol, a branched aliphatic group, and/or the like as a spacer. The metal oxide nanoparticles may be present in an amount of about 10 wt % to about 15 wt % based on the total weight of the composition.

The solvent may be an alcohol-based solvent, an ether-based solvent, an aromatic solvent, or any combination thereof.

For example, the solvent may include methanol, ethanol, propanol, butanol, pentanol, cyclohexylbenzene, 1,3-dipropoxybenzene, 4-methoxybenzaldehyde-dimethyl-acetal, 4,4′-difluorodiphenylmethane, diphenylether, 1,2-dimethoxy-4-(1-propenyl)benzene, 2-phenoxytoluene (MDPE), diphenylmethane, 2-phenylpyridine, dimethyl benzylether (DMDPE), 3-phenoxytoluene, 3-phenylpyridine, 2-phenylanisole, 2-phenoxytetrahydrofuran, 1-propyl-4-phenyl benzene (NPBP), 2-phenoxy-1,4-dimethyl benzene (25DMDPE), ethyl-2-naphthyl ether, dodecylbenzene, 2,2,5-tri-methyldiphenyl ether (225TMDPE), dibenzyl ether, 2,3,5-tri-methyl diphenyl ether (235TMDPE), N-methyldiphenylamine, 4-isopropylbiphenyl, α,α-dichlorodiphenylmethane, 4-(3-phenylpropyl)pyridine, benzyl benzoate, 1,1-bis(3,4-dimethylphenyl)ethane, diethylene glycol butyl methyl ether (DEGBME), diethylene glycol monomethyl ether (DEGME), diethylene glycol ethyl methyl ether (DEGEME), diethylene glycol dibutyl ether (DEGDBE), propylene glycol methyl ether acetate (PGMEA), triethylene glycol monomethyl ether (TGME), diethylene glycol monobutyl ether (DGBE), diethylene glycol t-butyl ether, triethylene glycol isopropyl ether, tripropylene glycol monobutyl ether, diethylene glycol-2-ethylhexyl ether, tetraethylene glycol monomethyl ether, ethylene glycol monomethyl ether, propylene glycol monomethyl ether, propylene glycol monomethyl ether acetate, propylene glycol monopropyl ether, tripropylene glycol monomethyl ether, or any combination thereof.

For example, the solvent may be a solvent including glycol. The metal oxide nanoparticles and the polymer may be stably mixed in the solvent. The metal oxide nanoparticle composition may maintain stability with time for two or more weeks in a mixed state.

### Light-Emitting Device

A light emitting element according to another embodiment includes:
an anode;
a cathode facing the anode; and
an interlayer including an emission layer and an electron transport region, wherein the emission layer is between the anode and the cathode and the electron transport region is between the emission layer and the cathode,
wherein the electron transport region includes: metal oxide nanoparticles; and
a polymer including a moiety represented by Formula 1:

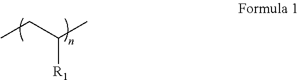

wherein, in Formula 1, R₁ is a functional group including two or more electron donor atoms, and n is an integer from 100 to 500. An amount of the polymer may be about 0.1 wt % to about 1 wt % of a weight of the metal oxide nanoparticles.

According to an embodiment, the polymer may further include a functional group such as a carbonyl group, a hydroxyl group, an amine group, an amide group, and/or the like in the backbone including or consisting of carbon chains.

According to an embodiment, the electron transport region may include an electron transport layer, and the electron transport layer may include the metal oxide nanoparticles and the polymer. In embodiments, the electron transport layer and the emission layer may be in contact (e.g., physical contact) with each other.

According to another embodiment, the electron transport region may include an electron transport layer and a polymer layer between the emission layer and the electron transport layer, and
the electron transport layer may include the metal oxide nanoparticles, and the polymer layer may include the polymer. In embodiments, the polymer layer and the emission layer may be in contact (e.g., physical contact) with each other.

For example, a thickness of the polymer layer may be about 1 nm to about 10 nm.

According to an embodiment, the electron donor atoms may include nitrogen (N) or oxygen (O).

According to an embodiment, the functional groups R₁ may each independently include one of structures 1 to 4 below:

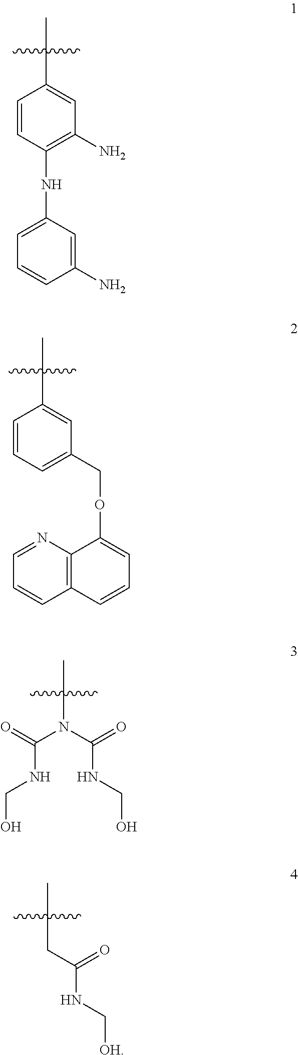 [SMILES: *c1ccc(Nc2cccc(N)c2)c(N)c1 ; *c1cccc(COc2cccc3cccnc23)c1 ; *N(C(=O)NCO)C(=O)NCO ; *CC(=O)NCO]

The polymer may have, for example, a weight average molecular weight (Mw) of about 10,000 to about 50,000.

The metal oxide nanoparticles may include, but are not limited to, ZnO, ZnMgO, ZnMgO:Sn, ZnSnO, ZnAlO, SnO₂, TiO₂, or any combination thereof. The metal oxide nanoparticles may be selected from among suitable metal oxides having electron transport capability.

According to an embodiment, a diameter of the metal oxide nanoparticle may be, for example, about 3 nm to about 5 nm. According to an embodiment, the metal oxide nanoparticle may include a ligand on the surface thereof. For example, the ligand may include a thiol group, a carboxyl group, an amino group, a catechol group, an amide group, a thioacetic acid group, and/or the like as an anchoring group, and may include ethylene glycol, a branched aliphatic group, and/or the like as a spacer. The metal oxide nanoparticles may be present in an amount of about 10 wt % to about 15 wt % based on the total weight of the composition.

The emission layer may be an emission layer including quantum dots.

The quantum dot may be a Group II-VI semiconductor compound.

Examples of the Group II-VI semiconductor compound may include a binary compound, such as CdS, CdSe, CdTe, ZnS, ZnSe, ZnTe, ZnO, HgS, HgSe, HgTe, MgSe, MgS, and the like; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and the like; a quaternary compound, such as CdZnSeS, CdZnSeTe, CdZnSTe, CdHgSeS, CdHgSeTe, CdHgSTe, HgZnSeS, HgZnSeTe, HgZnSTe, and the like; or any combination thereof.

The quantum dot may be a quantum dot including, for example, Cd.

The quantum dot may include, for example, CdS, CdSe, CdTe, CdSeS, CdSeTe, CdSTe, CdZnS, CdZnSe, CdZnTe, CdHgS, CdHgSe, CdHgTe, CdZnSeS, CdZnSeTe, CdZnSTe, CdHgSeS, CdHgSeTe, CdHgSTe, or any combination thereof. A size (e.g., diameter) of the quantum dot may be, for example, about 1 nm to about 10 nm.

An electron transport layer including metal oxide nanoparticles may quench quantum dot luminescence due to oxygen vacancy in the metal oxide when in contact (e.g., physical contact) with a quantum dot emission layer. When the electron transport layer includes the polymer according to the embodiment, the probability that the metal oxide nanoparticles in the electron transport layer and the quantum dots in the emission layer are in contact (e.g., physical contact) with each other at the interface between the electron transport layer and the emission layer may be reduced, thereby reducing the quenching of quantum dot luminescence. The reduction of the quenching of quantum dot luminescence may improve the efficiency of a light-emitting device.

In an embodiment, by providing a separate polymer layer between the electron transport layer and the emission layer instead of including the polymer in the electron transport layer, the quenching of quantum dot luminescence may be reduced, thereby improving the efficiency of a light-emitting device.

In embodiments, the polymer may chelate metal ions derived from metal components constituting a quantum dot in the quantum dot emission layer with a functional group including the electron donor atoms. When the quantum dot is a Group II-VI semiconductor compound, the semiconductor compound may have ionic bonding properties, and thus, some of Group II elements constituting the quantum dot may be separated into ions and exist within the emission layer. Such metal ions derived from a quantum dot may be heavy metals which are environmentally regulated substances, and may have adverse effects on the human body.

An electron transport layer and/or polymer layer including the polymer adjacent to the quantum dot emission layer may chelate the metal ions moving from the quantum dot emission layer, thereby preventing or reducing heavy metal elution due to the metal ions.

According to another embodiment, provided is an electronic device including the light-emitting device as described above. The electronic device may further include a thin-film transistor. For example, the electronic device may further include a thin-film transistor including a source electrode and a drain electrode, wherein an anode or a cathode of the light-emitting device may be electrically connected to the source electrode or the drain electrode. In an embodiment, the electronic device may further include a color filter, a color conversion layer, a touch screen layer, a polarizing layer, or any combination thereof.

For more details on the electronic device, related descriptions provided herein may be referred to.

According to another embodiment, provided is an electronic apparatus including the light-emitting device as described above.

For example, the electronic apparatus may be one selected from among a flat panel display, a curved display, a computer monitor, a medical monitor, a television, a billboard, an indoor light, an outdoor light, a signal light, a head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle, a video wall having a plurality of displays tiled together, a theater screen, a stadium screen, a phototherapy device, and a signboard.

More details on the electronic apparatus may be the same as described herein.

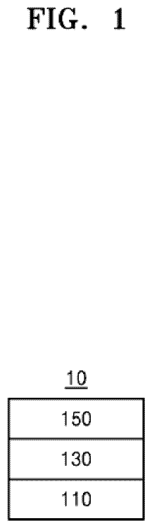

### Description of FIG. 1

FIG. 1 is a schematic cross-sectional view of the structure of a light-emitting device 10 according to an embodiment. The light-emitting device 10 includes a first electrode 110, an interlayer 130, and a second electrode 150.

Hereinafter, the structure of the light-emitting device 10 according to an embodiment and a method of manufacturing the light-emitting device 10 will be described with reference to FIG. 1.

### First Electrode 110

In FIG. 1, a substrate may be under the first electrode 110 and/or on the second electrode 150. As the substrate, a glass substrate and/or a plastic substrate may be used. In one or more embodiments, the substrate may be a flexible substrate, and may include, for example, plastics having excellent heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing and/or sputtering a material to form the first electrode 110 on the substrate. When the first electrode 110 is an anode, a material for forming the first electrode 110 may be a high-work function material that facilitates injection of holes.

The first electrode 110 may be a reflective electrode, a transflective electrode, or a transmissive electrode. When the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In one or more embodiments, when the first electrode 110 is a transflective electrode or a reflective electrode, a material for forming the first electrode 110 may include magnesium (Mg), silver (Ag), aluminum (AI), aluminum-lithium (Al—Li), calcium (Ca), magnesium-indium (Mg—In), magnesium-silver (Mg—Ag), or any combination thereof.

The first electrode 110 may have a single-layered structure consisting of a single layer or a multi-layered structure including a plurality of layers. For example, the first electrode 110 may have a three-layered structure of ITO/Ag/ITO.

### Interlayer 130

The interlayer 130 may be on the first electrode 110. The interlayer 130 may include an emission layer.

The interlayer 130 may further include a hole transport region between the first electrode 110 and the emission layer, and an electron transport region between the emission layer and the second electrode 150.

The interlayer 130 may further include, in addition to various suitable organic materials, a metal-containing compound, an inorganic material such as quantum dots, and/or the like.

In an embodiment, the interlayer 130 may include i) two or more emitting units sequentially stacked between the first electrode 110 and the second electrode 150, and ii) a charge generation layer between adjacent emitting units among the two or more emitting units. When the interlayer 130 includes emitting units and a charge generation layer as described above, the light-emitting device 10 may be a tandem light-emitting device.

### Hole Transport Region in Interlayer 130

The hole transport region may include metal oxide nanoparticles and/or nanocomposites including the metal oxide nanoparticles.

The hole transport region may have i) a single-layered structure consisting of a single layer consisting of a single material, ii) a single-layered structure consisting of a single layer consisting of a plurality of different materials, or iii) a multi-layered structure including a plurality of layers including a plurality of different materials.

The hole transport region may include a hole injection layer, a hole transport layer, an emission auxiliary layer, an electron-blocking layer, or any combination thereof.

For example, the hole transport region may have a multi-layered structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron-blocking layer structure, the layers of each structure being stacked sequentially from the first electrode 110.

The hole transport region may include a compound represented by Formula 201, a compound represented by Formula 202, or any combination thereof:

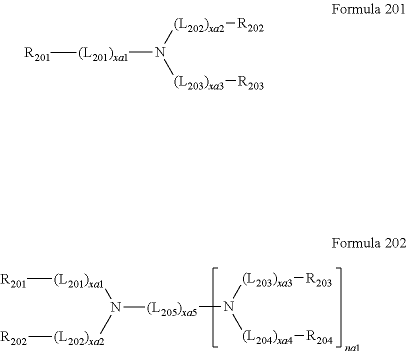

wherein, in Formulae 201 and 202,
L₂₀₁ to L₂₀₄ may each independently be a divalent C₃-C₆₀ carbocyclic group unsubstituted or substituted with at least one R₁₀ₐ or a divalent C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a divalent C₃-C₆₀ carbocyclic group unsubstituted or substituted with at least one R₁₀ₐ, or a divalent C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ, or a C₁-C₆₀ heterocyclic group unsubstituted or substituted with at least one R₁₀ₐ,
R₂₀₁ and R₂₀₂ may optionally be linked to each other, via a single bond (e.g., a single covalent bond), a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group (for example, a carbazole group and/or the like) unsubstituted or substituted with at least one R₁₀ₐ (for example, see Compound HT16),
R₂₀₃ and R₂₀₄ may optionally be linked to each other, via a single bond (e.g., a single covalent bond), a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ,
na1 may be an integer from 1 to 4, and

*, *′, and R₁₀ₐ are the same as described herein.

For example, each of Formulae 201 and 202 may include at least one selected from among groups represented by Formulae CY201 to CY217:

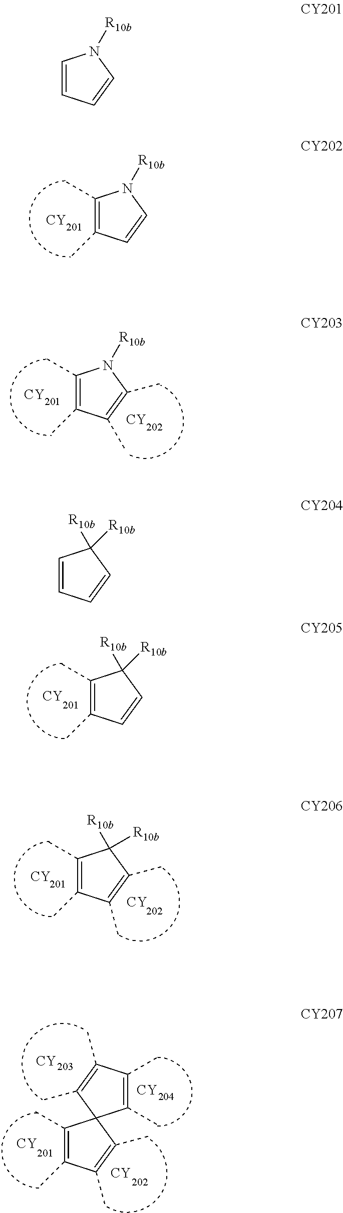

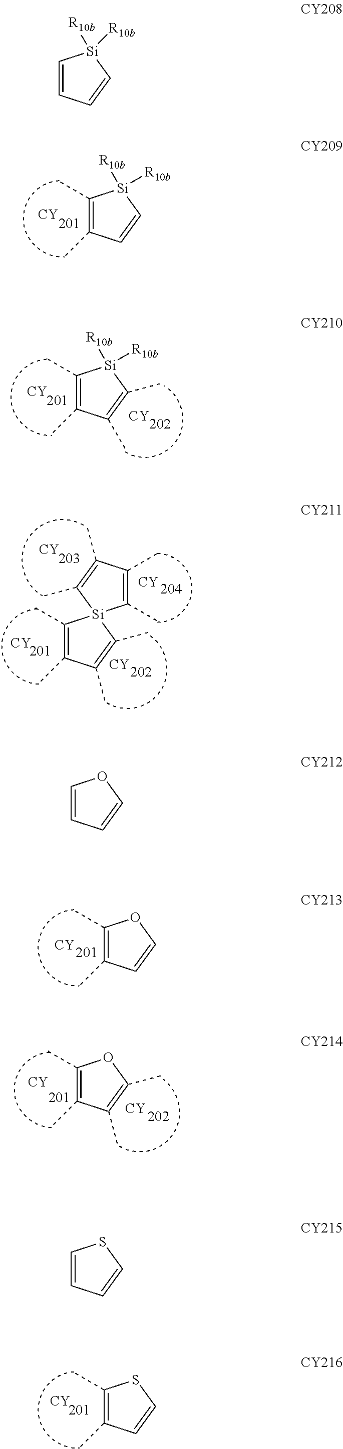

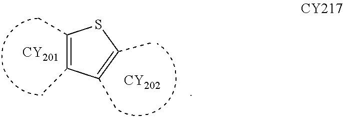

wherein, in Formulae CY201 to CY217, R_{10b} and R_{10c} may each be as described herein in connection with R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ as described herein.

According to an embodiment, in Formulae CY201 to CY217, ring CY₂₀₁ to ring CY₂₀₄ may each independently be a benzene group, a naphthalene group, a phenanthrene group, or an anthracene group.

According to another embodiment, each of Formulae 201 and 202 may include at least one selected from among groups represented by Formulae CY201 to CY203.

According to another embodiment, Formula 201 may include at least one selected from among the groups represented by Formulae CY201 to CY203 and at least one selected from among the groups represented by Formulae CY204 to CY217.

According to another embodiment, in Formula 201, xa1 may be 1, R₂₀₁ may be a group represented by one selected from among Formulae CY201 to CY203, xa2 may be 0, and R₂₀₂ may be a group represented by one selected from among Formulae CY204 to CY207.

According to another embodiment, each of Formulae 201 and 202 may not include a group represented by one selected from among Formulae CY201 to CY203.

According to another embodiment, each of Formulae 201 and 202 may not include groups represented by Formulae CY201 to CY203, and may include at least one selected from among groups represented by Formulae CY204 to CY217.

According to another embodiment, each of Formulae 201 and 202 may not include the groups represented by Formulae CY201 to CY217.

For example, the hole transport region may include one selected from among Compounds HT1 to HT47, m-MTDATA, TDATA, 2-TNATA, NPB(NPD), β-NPB, TPD, Spiro-TPD, Spiro-NPB, methylated-NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof:

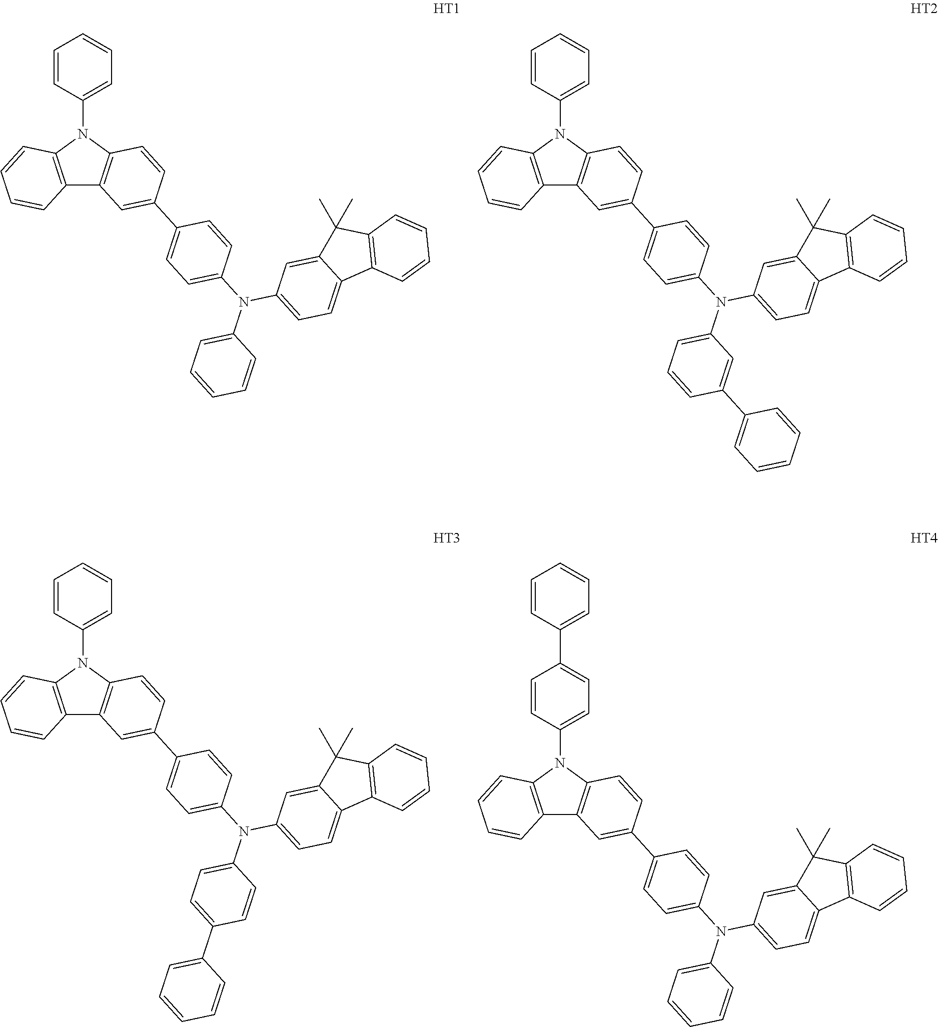 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

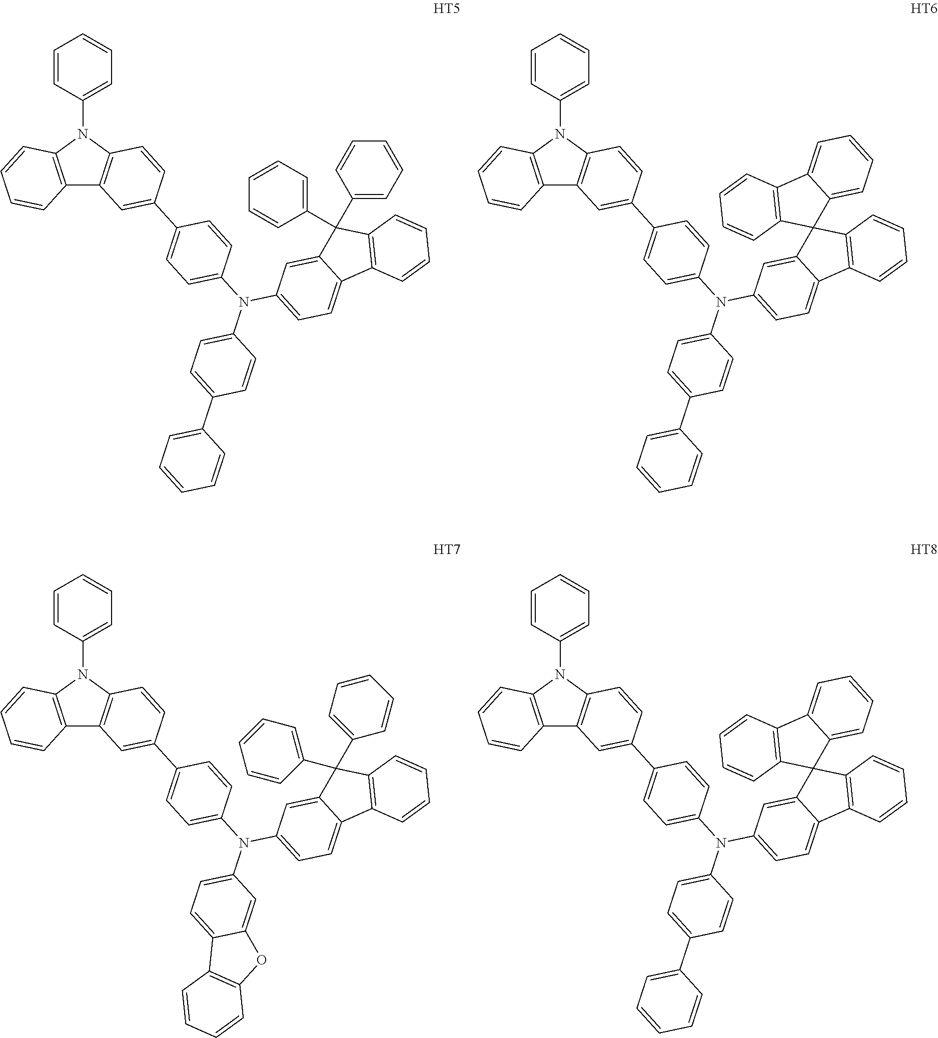 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

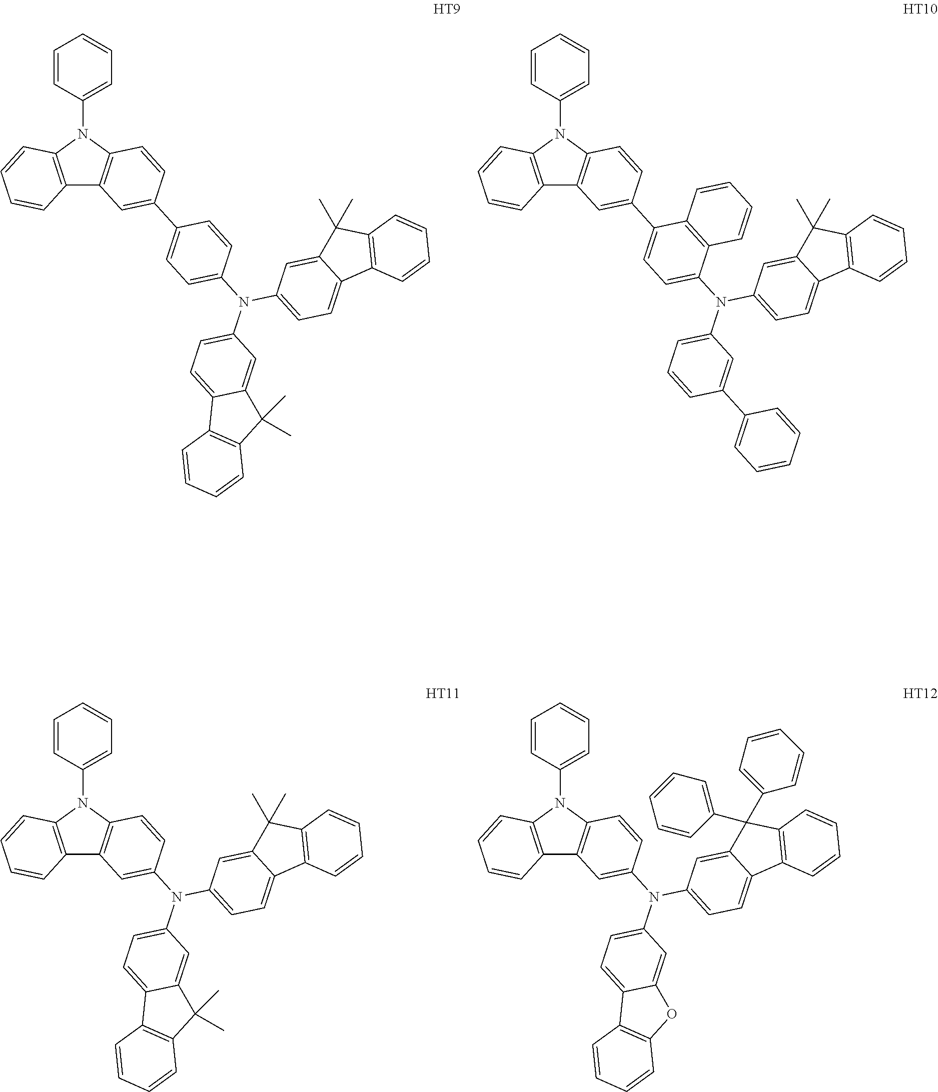 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

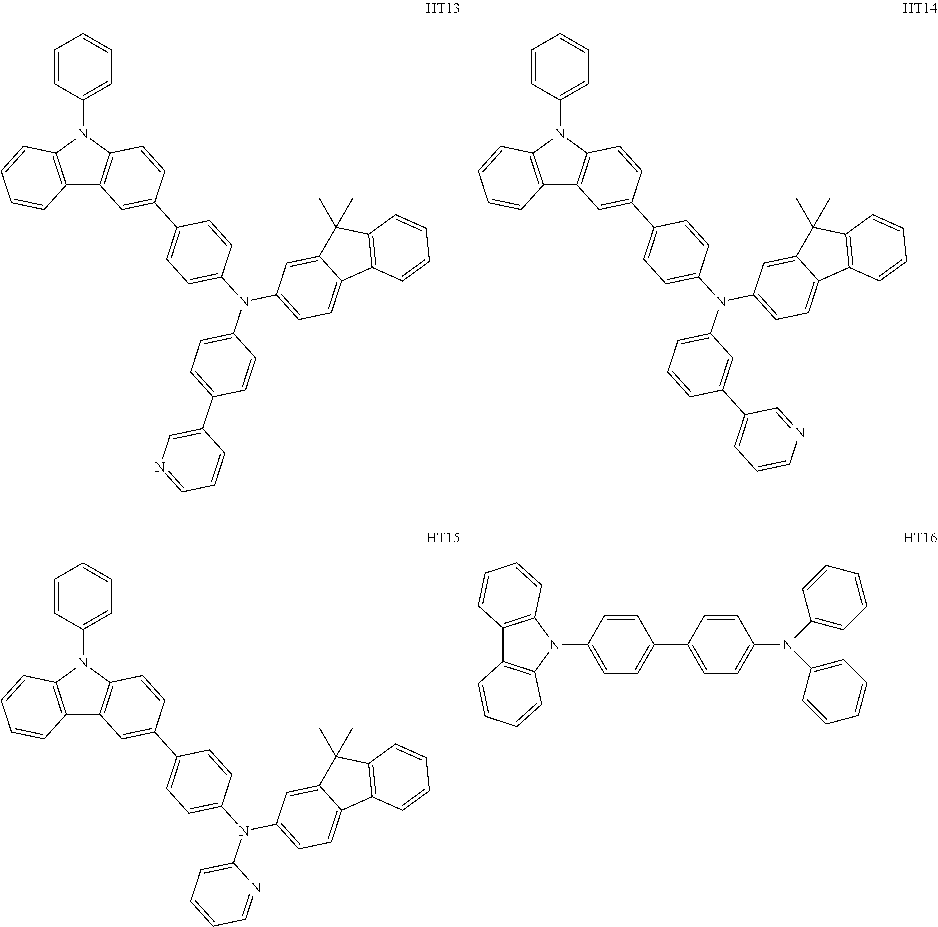 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1]

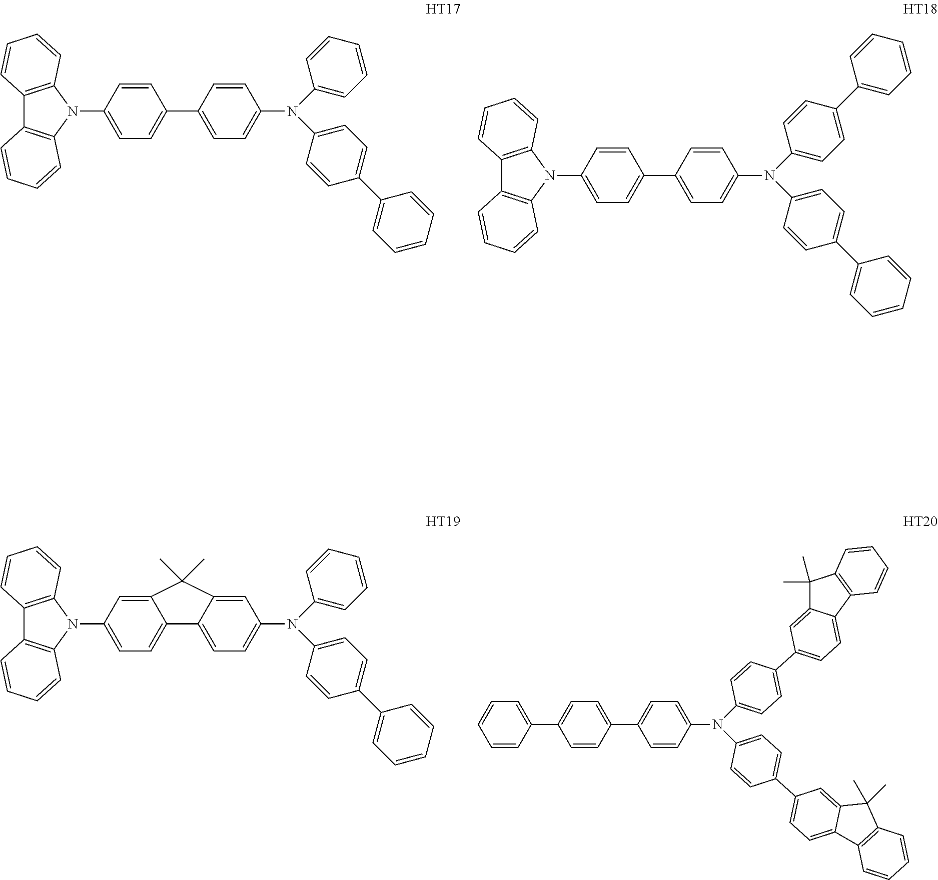 [SMILES: c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21]

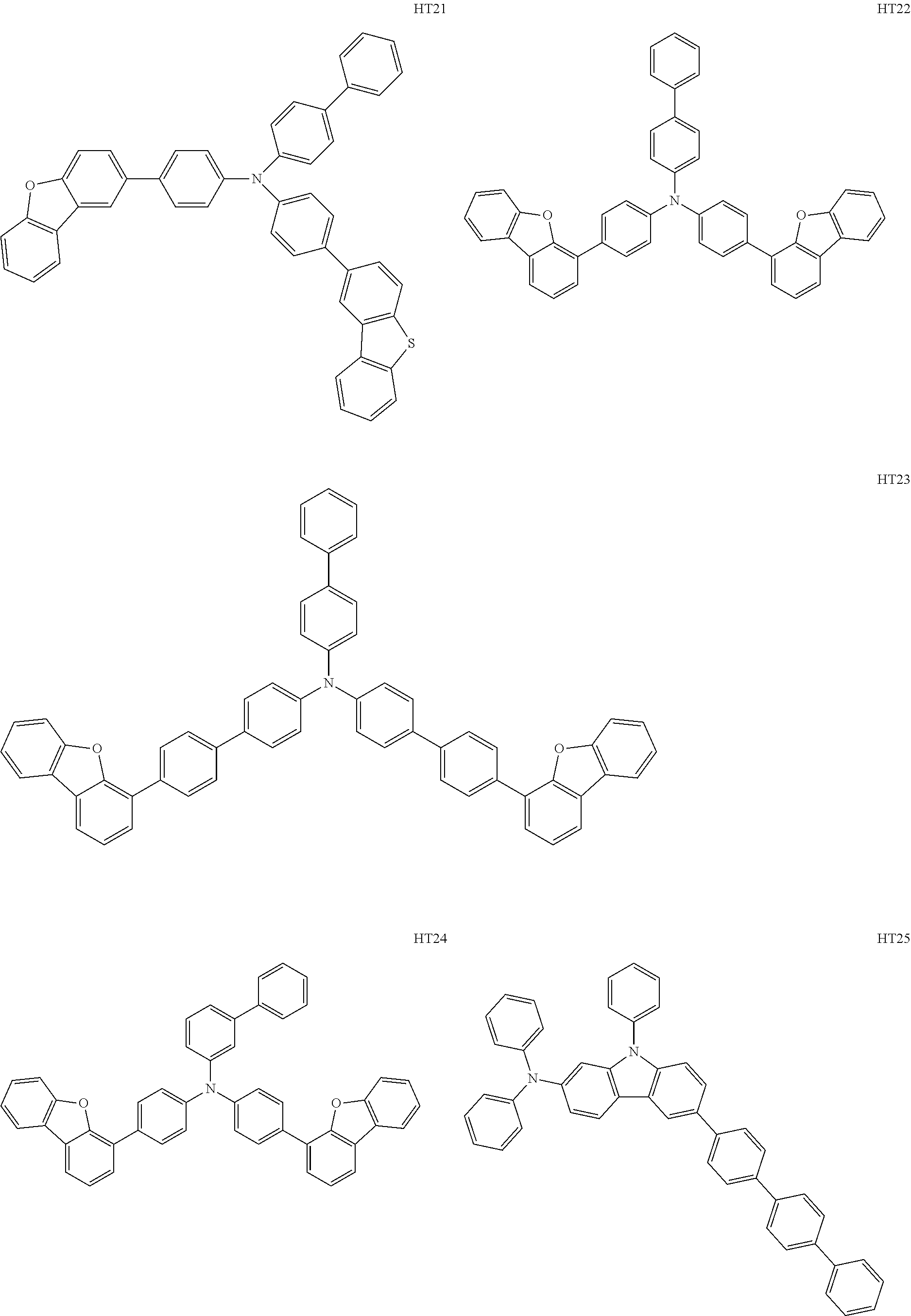 [SMILES: c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1 ; c1ccc(-c2cccc(N(c3ccc(-c4cccc5c4oc4ccccc45)cc3)c3ccc(-c4cccc5c4oc4ccccc45)cc3)c2)cc1 ; c1ccc(-c2ccc(-c3ccc(-c4ccc5c(c4)c4ccc(N(c6ccccc6)c6ccccc6)cc4n5-c4ccccc4)cc3)cc2)cc1]

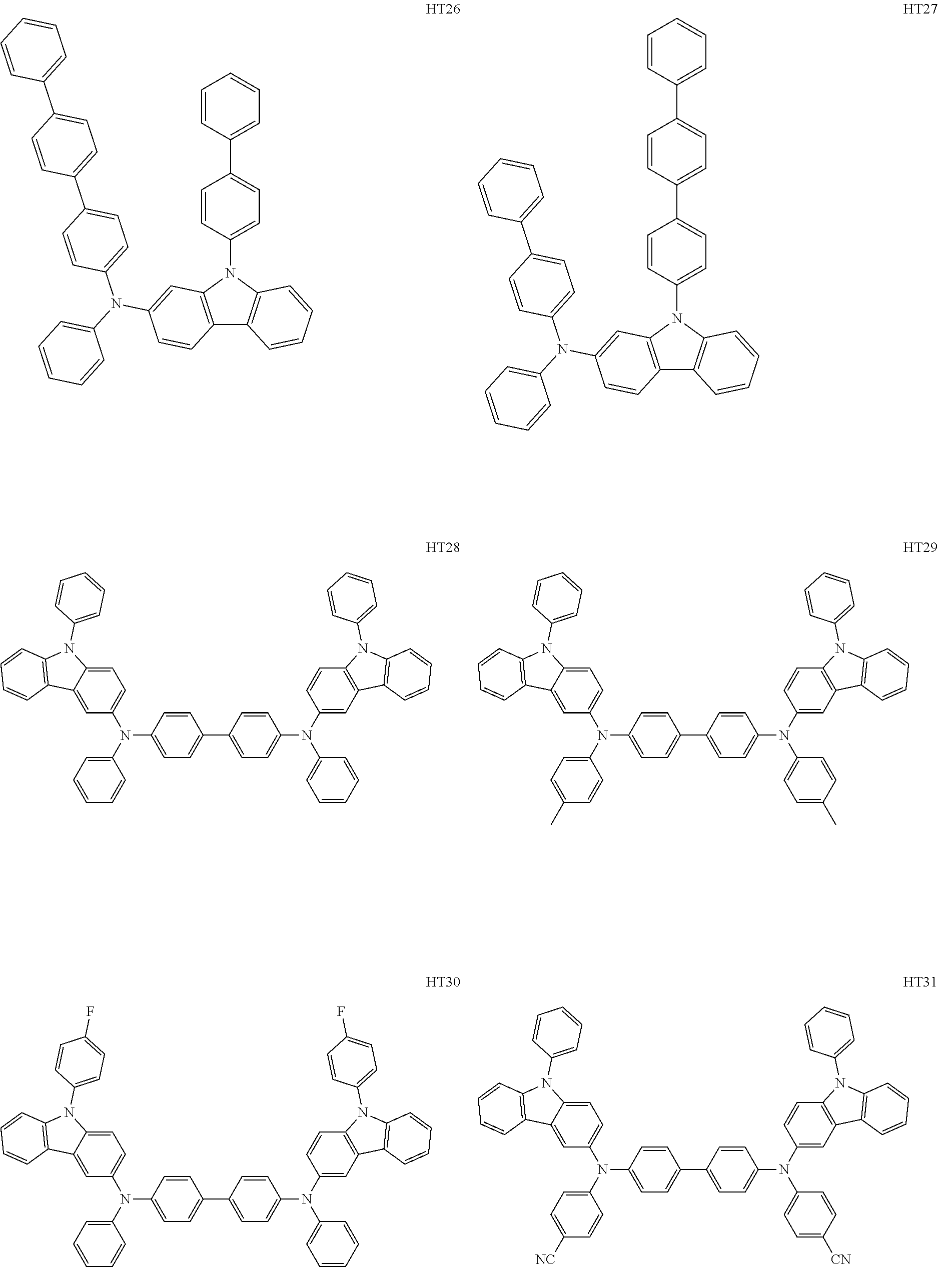

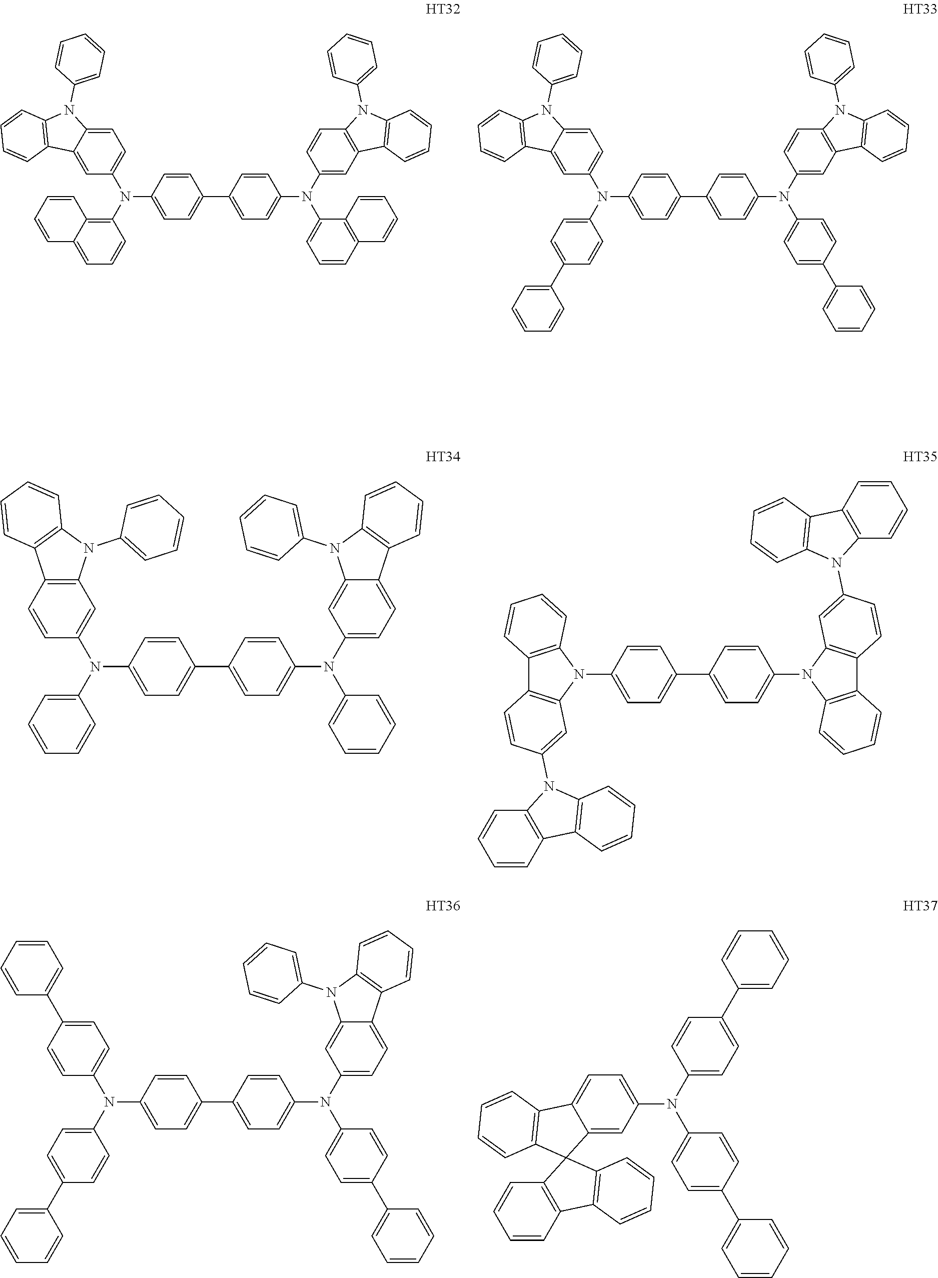

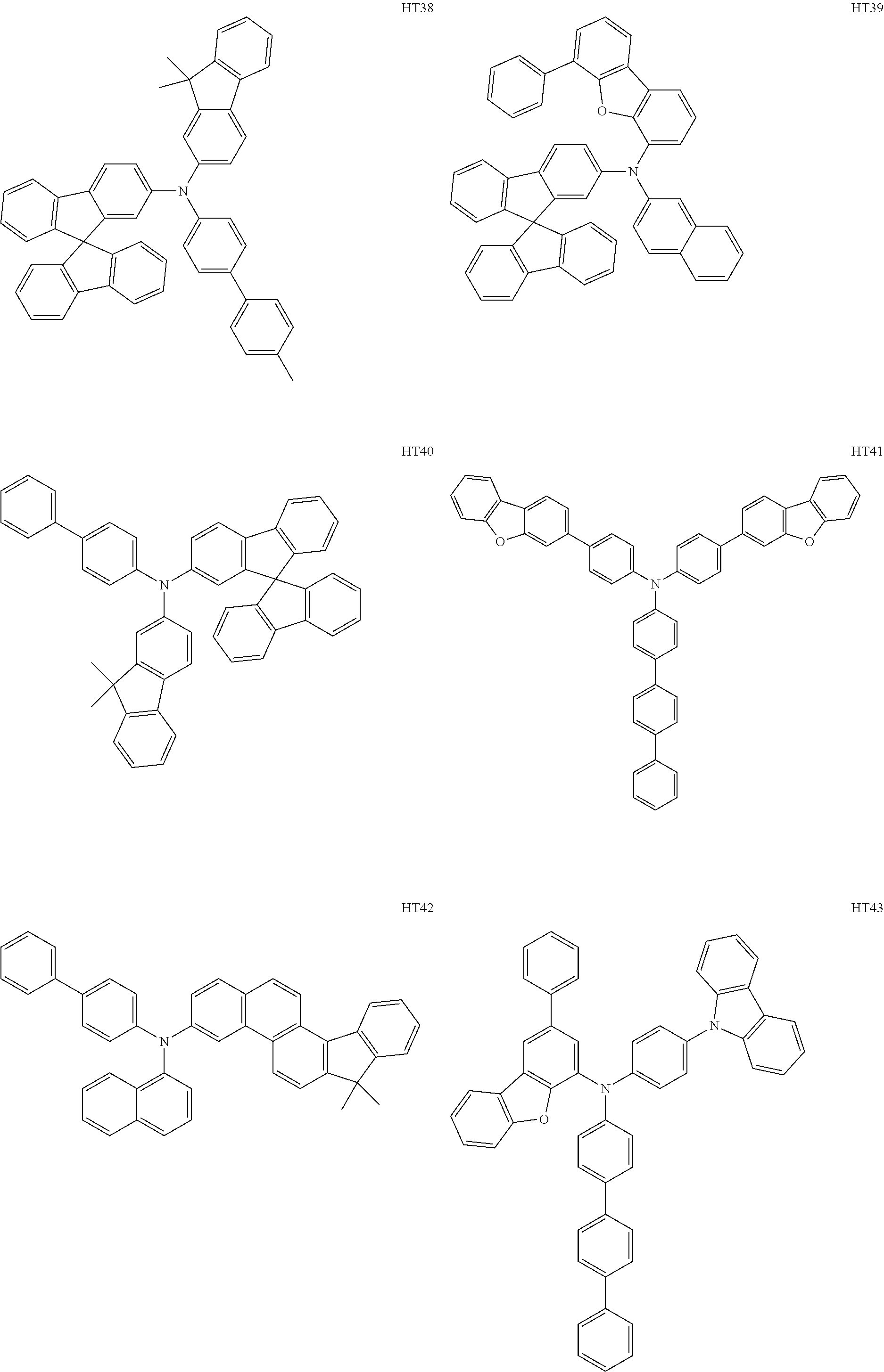

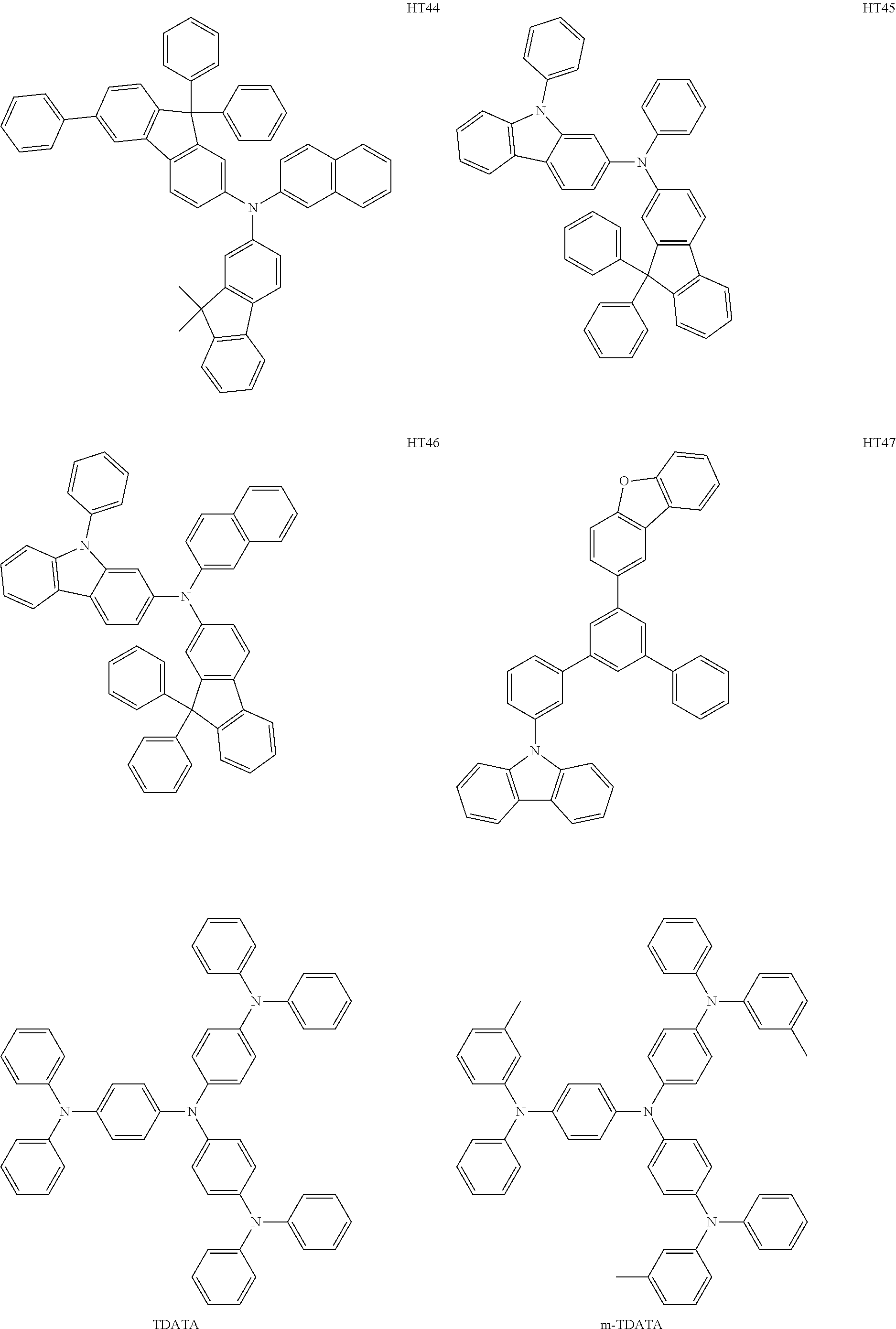

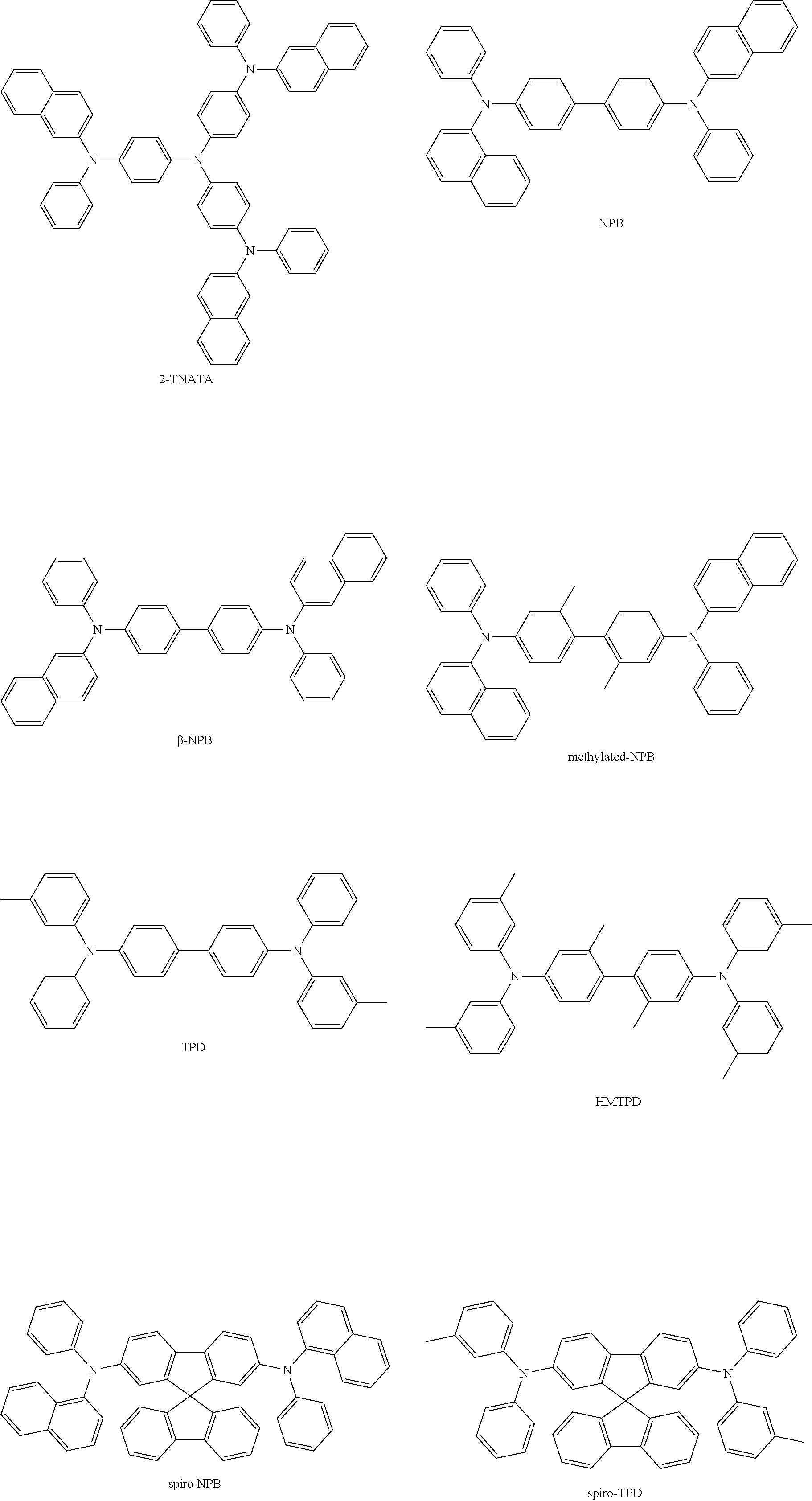

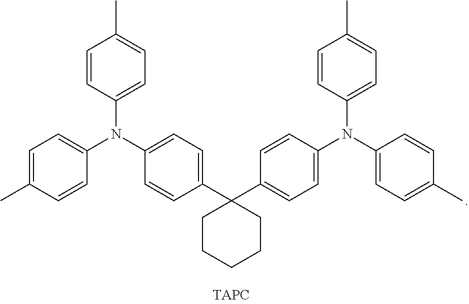

A thickness of the hole transport region may be in a range of about 50 Å to about 10,000 Å, for example, about 100 Å to about 4,000 Å. When the hole transport region includes a hole injection layer, a hole transport layer, or any combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer, and the hole transport layer are within these ranges, suitable or satisfactory hole transporting characteristics may be obtained without a substantial increase in driving voltage.

The emission auxiliary layer may increase light-emitting efficiency by compensating for an optical resonance distance according to the wavelength of light emitted by an emission layer, and the electron-blocking layer may block or reduce the leakage of electrons from an emission layer to a hole transport region. Materials that may be included in the hole transport region may be included in the emission auxiliary layer and the electron-blocking layer.

p-Dopant

The hole transport region may further include, in addition to these materials, a charge-generation material for the improvement of conductive properties (e.g., electrically conductive properties). The charge-generation material may be uniformly or non-uniformly dispersed in the hole transport region (for example, in the form of a single layer consisting of a charge-generation material).

The charge-generation material may be, for example, a p-dopant.

For example, the p-dopant may have a lowest unoccupied molecular orbital (LUMO) energy level of −3.5 eV or less.

According to an embodiment, the p-dopant may include a quinone derivative, a cyano group-containing compound, a compound including element EL1 and element EL2, or any combination thereof.

Examples of the quinone derivative may include TCNQ, F4-TCNQ, and the like.

Examples of the cyano group-containing compound may include HAT-CN, a compound represented by Formula 221, and the like:

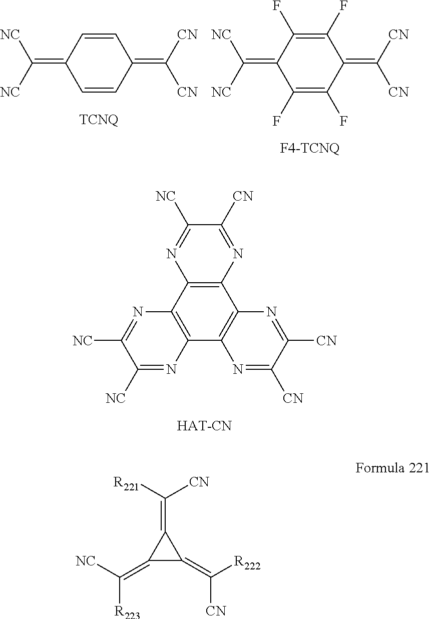

wherein, in Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one selected from among R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound including element EL1 and element EL2, element EL1 may be metal, metalloid, or any combination thereof, and element EL2 may be non-metal, metalloid, or any combination thereof.

Examples of the metal may include: alkali metal (for example, lithium (Li), sodium (Na), potassium (K), rubidium (Rb), cesium (Cs), and/or the like); alkaline earth metal (for example, beryllium (Be), magnesium (Mg), calcium (Ca), strontium (Sr), barium (Ba), and/or the like); transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and/or the like); post-transition metal (for example, zinc (Zn), indium (In), tin (Sn), and/or the like); lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and/or the like); and the like.

Examples of the metalloid may include silicon (Si), antimony (Sb), tellurium (Te), and the like.

Examples of the non-metal may include oxygen (O), a halogen (for example, F, Cl, Br, I, and/or the like), and the like.

For example, the compound including element EL1 and element EL2 may include metal oxide, metal halide (for example, metal fluoride, metal chloride, metal bromide, metal iodide, and/or the like), metalloid halide (for example, metalloid fluoride, metalloid chloride, metalloid bromide, metalloid iodide, and/or the like), metal telluride, or any combination thereof.

Examples of the metal oxide may include tungsten oxide (for example, WO, W₂O₃, WO₂, WO₃, W₂O₅, and/or the like), vanadium oxide (for example, VO, V₂O₃, VO₂, V₂O₅, and/or the like), molybdenum oxide (for example, MoO, Mo₂O₃, MoO₂, MoO₃, Mo₂O₅, and/or the like), rhenium oxide (for example, ReO₃, and/or the like), and the like.

Examples of the metal halide may include alkali metal halide, alkaline earth metal halide, transition metal halide, post-transition metal halide, lanthanide metal halide, and the like.

Examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, CsI, and the like.

Examples of the alkaline earth metal halide may include BeF₂, MgF₂, CaF₂, SrF₂, BaF₂, BeCl₂, MgCl₂, CaCl₂, SrCl₂, BaCl₂, BeBr₂, MgBr₂, CaBr₂, SrBr₂, BaBr₂, BeI₂, MgI₂, CaI₂, SrI₂, BaI₂, and the like.

Examples of the transition metal halide may include titanium halide (for example, TiF₄, TiC₄, TiBr₄, TiI₄, and/or the like), zirconium halide (for example, ZrF₄, ZrCl₄, ZrBr₄, ZrI₄, and/or the like), hafnium halide (for example, HfF₄, HfCl₄, HfBr₄, HfI₄, and/or the like), vanadium halide (for example, VF₃, VCl₃, VBr₃, VI₃, and/or the like), niobium halide (for example, NbF₃, NbCl₃, NbBr₃, NbI₃, and/or the like), tantalum halide (for example, TaF₃, TaCl₃, TaBr₃, TaI₃, and/or the like), chromium halide (for example, CrF₃, CrO₃, CrBr₃, CrI₃, and/or the like), molybdenum halide (for example, MoF₃, MoCl₃, MoBr₃, MoI₃, and/or the like), tungsten halide (for example, WF₃, WCl₃, WBr₃, WI₃, and/or the like), manganese halide (for example, MnF₂, MnCl₂, MnBr₂, MnI₂, and/or the like), technetium halide (for example, TcF₂, TcCl₂, TcBr₂, TcI₂, and/or the like), rhenium halide (for example, ReF₂, ReCl₂, ReBr₂, ReI₂, etc.), iron halide (for example, FeF₂, FeCl₂, FeBr₂, FeI₂, and/or the like), ruthenium halide (for example, RuF₂, RuCl₂, RuBr₂, RuI₂, and/or the like), osmium halide (for example, OsF₂, OsCl₂, OsBr₂, OsI₂, and/or the like), cobalt halide (for example, CoF₂, COCl₂, CoBr₂, CoI₂, and/or the like), rhodium halide (for example, RhF₂, RhCl₂, RhBr₂, RhI₂, and/or the like), iridium halide (for example, IrF₂, IrCl₂, IrBr₂, IrI₂, and/or the like), nickel halide (for example, NiF₂, NiCl₂, NiBr₂, NiI₂, and/or the like), palladium halide (for example, PdF₂, PdCl₂, PdBr₂, PdI₂, and/or the like), platinum halide (for example, PtF₂, PtCl₂, PtBr₂, PtI₂, and/or the like), copper halide (for example, CuF, CuCl, CuBr, CuI, and/or the like), silver halide (for example, AgF, AgCl, AgBr, AgI, and/or the like), gold halide (for example, AuF, AuCl, AuBr, AuI, and/or the like), and the like.

Examples of the post-transition metal halide may include zinc halide (for example, ZnF₂, ZnCl₂, ZnBr₂, ZnI₂, and/or the like), indium halide (for example, Ink₃, and/or the like), tin halide (for example, SnI₂, and/or the like), and the like.

Examples of the lanthanide metal halide may include YbF, YbF₂, YbF₃, SmF₃, YbCl, YbCl₂, YbCl₃ SmCl₃, YbBr, YbBr₂, YbBr₃, SmBr₃, YbI, YbI₂, YbI₃, SmI₃, and the like.

Examples of the metalloid halide may include antimony halide (for example, SbCl₅, and/or the like) and the like.

Examples of the metal telluride may include alkali metal telluride (for example, Li₂Te, Na₂Te, K₂Te, Rb₂Te, Cs₂Te, and/or the like), alkaline earth metal telluride (for example, BeTe, MgTe, CaTe, SrTe, BaTe, and/or the like), transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, and/or the like), post-transition metal telluride (for example, ZnTe, and/or the like), lanthanide metal telluride (for example, LaTe, CeTe, PrTe, NdTe, PmTe, EuTe, GdTe, TbTe, DyTe, HoTe, ErTe, TmTe, YbTe, LuTe, and/or the like), and the like.

### Emission Layer in Interlayer 130

When the light-emitting device 10 is a full-color light-emitting device, the emission layer may be patterned into a red emission layer, a green emission layer, and/or a blue emission layer, according to a subpixel. In one or more embodiments, the emission layer may have a stacked structure of two or more layers of a red emission layer, a green emission layer, and a blue emission layer, in which the two or more layers contact each other or are separated from each other to emit white light. In one or more embodiments, the emission layer may include two or more materials of a red light-emitting material, a green light-emitting material, and a blue light-emitting material, in which the two or more materials are mixed with each other in a single layer to emit white light.

### Quantum Dot

The emission layer may include quantum dots.

The term “quantum dot” as used herein refers to a crystal of a semiconductor compound, and may include any suitable material capable of emitting light of various suitable emission wavelengths according to the size of the crystal.

A diameter of the quantum dot may be, for example, in a range of about 1 nm to about 10 nm.

The quantum dot may be synthesized by a wet chemical process, a metal organic chemical vapor deposition process, a molecular beam epitaxy process, and/or any suitable process similar thereto.

The wet chemical process is a method including mixing a precursor material with an organic solvent and then growing a quantum dot particle crystal. When the crystals grow, the organic solvent naturally acts as a dispersant coordinated on the surface of the quantum dot crystals and controls the growth of the crystals so that the growth of quantum dot particles may be controlled through a process which costs lower and is easier than vapor deposition methods, such as metal organic chemical vapor deposition (MOCVD) or molecular beam epitaxy (MBE).

In the present embodiment, the quantum dot may include a Group II-VI semiconductor compound.

Examples of the Group II-VI semiconductor compound may include: a binary compound, such as CdS, CdSe, CdTe, ZnS, ZnSe, ZnTe, ZnO, HgS, HgSe, HgTe, MgSe, MgS, and/or the like; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or the like; a quaternary compound, such as CdZnSeS, CdZnSeTe, CdZnSTe, CdHgSeS, CdHgSeTe, CdHgSTe, HgZnSeS, HgZnSeTe, HgZnSTe, and/or the like; or any combination thereof.

Each element included in a multi-element compound such as the binary compound, the ternary compound, and the quaternary compound may be present at a uniform concentration or non-uniform concentration in a particle.

In an embodiment, the quantum dot may have a single structure in which the concentration of each element in the quantum dot is uniform (e.g., substantially uniform), or a core-shell dual structure. For example, the material included in the core and the material included in the shell may be different from each other.

The shell of the quantum dot may serve as a protective layer to maintain semiconductor characteristics by preventing or reducing chemical modification of the core and/or to increase luminescence efficiency and stability. The shell may be a single layer or a multi-layer. The interface between the core and the shell may have a concentration gradient in which the concentration of an element existing in the shell decreases along a direction toward the center of the core.

Examples of the shell of the quantum dot may include an oxide of metal, metalloid, and/or non-metal, a semiconductor compound, or any combination thereof. Examples of the oxide of metal, metalloid, and/or non-metal may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and/or the like; a ternary compound, such as MgAl₂O₄, CoFe₂O₄, NiFe₂O₄, CoMn₂O₄, and/or the like; or any combination thereof. Examples of the semiconductor compound may include: as described above, a Group II-VI semiconductor compound; a Group III-V semiconductor compound; a Group Ill-VI semiconductor compound; a Group 1-III-VI semiconductor compound; a Group IV-VI semiconductor compound; or any combination thereof. For example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

A full width at half maximum (FWHM) of the emission wavelength spectrum of the quantum dot may be about 45 nm or less, for example, about 40 nm or less, for example, about 30 nm or less, and within these ranges, color purity and/or color reproducibility may be increased. In embodiments, because the light emitted through the quantum dot is emitted in all (e.g., substantially all) directions, the wide viewing angle may be improved.

In embodiments, the quantum dot may be in the form of a spherical particle, a pyramidal nanoparticle, a multi-arm nanoparticle, a cubic nanoparticle, a nanotube, a nanowire, a nanofiber, and/or a nanoplate.

Because the energy band gap may be adjusted by controlling the size of the quantum dot, light having various suitable wavelength bands may be obtained from the quantum dot emission layer. Accordingly, by using quantum dots of different sizes, a light-emitting device that emits light of various suitable wavelengths may be implemented. In more detail, the size of the quantum dot may be selected to emit red light, green light, and/or blue light. In embodiments, the size of the quantum dot may be configured to emit white light by combination of light of various suitable colors.

### Electron Transport Region in Interlayer 130

The electron transport region may include an electron transport layer including the metal oxide nanoparticles and the polymer including a moiety represented by Formula 1 as described above, or may include an electron transport layer including the metal oxide nanoparticles and a polymer layer including the polymer as described above.

The electron transport region may have i) a single-layered structure consisting of a single layer consisting of a single material, ii) a single-layered structure consisting of a single layer consisting of a plurality of different materials, or iii) a multi-layered structure including a plurality of layers including a plurality of different materials.

A thickness of the electron transport region may be in a range of about 100 Å to about 1,000 Å, for example, about 150 Å to about 1,000 Å, for example, about 200 Å to about 500 Å.

The electron transport region may include an electron injection layer that facilitates the injection of electrons from the second electrode 150. The electron injection layer may be in direct contact (e.g., physical contact) with the second electrode 150. The electron injection layer may be composed of, for example, nanoparticles of a metal oxide different from the metal oxide of the electron transport layer.

A thickness of the electron injection layer may be in a range of about 1 Å to about 100 Å, or, for example, about 3 Å to about 90 Å. When the thickness of the electron injection layer is within these ranges, suitable or satisfactory electron injection characteristics may be obtained without a substantial increase in driving voltage.

### Second Electrode 150

The second electrode 150 may be on the interlayer 130 having a structure as described above. The second electrode 150 may be a cathode, which is an electron injection electrode, and as a material for the second electrode 150, a metal, an alloy, an electrically conductive compound, or any combination thereof, each having a low-work function, may be used.

The second electrode 150 may include lithium (Li), silver (Ag), magnesium (Mg), aluminum (AI), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a transflective electrode, or a reflective electrode.

The second electrode 150 may have a single-layered structure or a multi-layered structure including a plurality of layers.

### Capping Layer

A first capping layer may be outside the first electrode 110, and/or a second capping layer may be outside the second electrode 150. In more detail, the light-emitting device 10 may have a structure in which the first capping layer, the first electrode 110, the interlayer 130, and the second electrode 150 are sequentially stacked in the stated order, a structure in which the first electrode 110, the interlayer 130, the second electrode 150, and the second capping layer are sequentially stacked in the stated order, or a structure in which the first capping layer, the first electrode 110, the interlayer 130, the second electrode 150, and the second capping layer are sequentially stacked in the stated order.

Light generated in an emission layer of the interlayer 130 of the light-emitting device 10 may be extracted toward the outside through the first electrode 110 which is a transflective electrode or a transmissive electrode, and the first capping layer. Light generated in an emission layer of the interlayer 130 of the light-emitting device 10 may be extracted toward the outside through the second electrode 150 which is a transflective electrode or a transmissive electrode, and the second capping layer.

The first capping layer and the second capping layer may increase external luminescence efficiency according to the principle of constructive interference. Accordingly, the light extraction efficiency of the light-emitting device 10 may be increased, and thus, the luminescence efficiency of the light-emitting device 10 may be improved.

Each of the first capping layer and the second capping layer may include a material having a refractive index of 1.6 or more (at a wavelength of 589 nm).

The first capping layer and the second capping layer may each independently be an organic capping layer including an organic material, an inorganic capping layer including an inorganic material, or an organic-inorganic composite capping layer including an organic material and an inorganic material.

At least one selected from among the first capping layer and the second capping layer may each independently include carbocyclic compounds, heterocyclic compounds, amine group-containing compounds, porphine derivatives, phthalocyanine derivatives, naphthalocyanine derivatives, alkali metal complexes, alkaline earth metal complexes, or any combination thereof. The carbocyclic compound, the heterocyclic compound, and the amine group-containing compound may optionally be substituted with a substituent including O, N, S, Se, Si, F, Cl, Br, I, or any combination thereof. According to an embodiment, at least one selected from among the first capping layer and the second capping layer may each independently include an amine group-containing compound.

For example, at least one selected from among the first capping layer and the second capping layer may each independently include a compound represented by Formula 201, a compound represented by Formula 202, or any combination thereof.

According to another embodiment, at least one selected from among the first capping layer and the second capping layer may each independently include one selected from among Compounds HT28 to HT33, one selected from among Compounds CP1 to CP6, β-NPB, or any combination thereof:

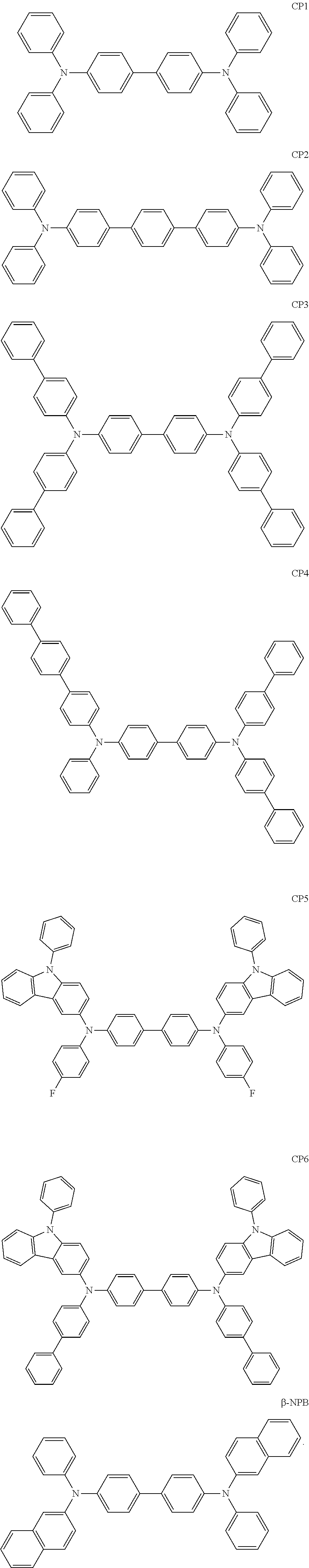

### Electronic Device

The light-emitting device may be included in various suitable electronic device. For example, the electronic device including the light-emitting device may be a light-emitting apparatus, an authentication apparatus, and/or the like.

The electronic device (for example, a light-emitting apparatus) may further include, in addition to the light-emitting device, i) a color filter, ii) a color conversion layer, or iii) a color filter and a color conversion layer. The color filter and/or the color conversion layer may be provided in at least one direction in which light emitted from the light-emitting device travels. For example, the light emitted from the light-emitting device may be blue light, green light, or white light. Details on the light-emitting device may be the same as the descriptions provided elsewhere herein. According to an embodiment, the color conversion layer may include quantum dots.

The electronic device may include a first substrate. The first substrate may include a plurality of subpixel areas, the color filter may include a plurality of color filter areas respectively corresponding to the subpixel areas, and the color conversion layer may include a plurality of color conversion areas respectively corresponding to the subpixel areas.

A pixel-defining film may be provided among the subpixel areas to define each of the subpixel areas.

The color filter may further include a plurality of color filter areas and light-shielding patterns provided among the color filter areas, and the color conversion layer may further include a plurality of color conversion areas and light-shielding patterns provided among the color conversion areas.

The plurality of color filter areas (or the plurality of color conversion areas) may include: a first area that emits a first color light; a second area that emits a second color light; and/or a third area that emits a third color light, wherein the first color light, the second color light, and/or the third color light may have different maximum emission wavelengths from one another. For example, the first color light may be red light, the second color light may be green light, and the third color light may be blue light. For example, the plurality of color filter areas (or the plurality of color conversion areas) may include quantum dots. In more detail, the first area may include a red quantum dot, the second area may include a green quantum dot, and the third area may not include a quantum dot. Details on the quantum dot may be the same as the descriptions provided elsewhere herein. The first area, the second area, and/or the third area may each further include a scatterer (e.g., a light scatterer).

For example, the light-emitting device may emit a first light, the first area may absorb the first light to emit a first-1 color light, the second area may absorb the first light to emit a second-1 color light, and the third area may absorb the first light to emit a third-1 color light. In embodiments, the first-1 color light, the second-1 color light, and the third-1 color light may have different maximum emission wavelengths. In more detail, the first light may be blue light, the first-1 color light may be red light, the second-1 color light may be green light, and the third-1 color light may be blue light.

The electronic device may further include a thin-film transistor, in addition to the light-emitting device as described above. The thin-film transistor may include a source electrode, a drain electrode, and an active layer, wherein any one selected from among the source electrode and the drain electrode may be electrically connected to one of the first electrode and the second electrode of the light-emitting device.

The thin-film transistor may further include a gate electrode, a gate insulating film, and/or the like.

The active layer may include crystalline silicon, amorphous silicon, an organic semiconductor, an oxide semiconductor, and/or the like.

The electronic device may further include a sealing portion to seal the light-emitting device. The sealing portion may be between the color filter and/or the color conversion layer and the light-emitting device. The sealing portion allows light from the light-emitting device to be extracted to the outside, and concurrently (e.g., simultaneously) prevents or reduces penetration of ambient air and moisture into the light-emitting device. The sealing portion may be a sealing substrate including a transparent glass substrate and/or a plastic substrate. The sealing portion may be a thin-film encapsulation layer including at least one layer of an organic layer and/or an inorganic layer. When the sealing portion is a thin-film encapsulation layer, the electronic device may be flexible.

Various suitable functional layers may be on the sealing portion, in addition to the color filter and/or the color conversion layer, according to the use of the electronic device. Examples of the functional layers may include a touch screen layer, a polarizing layer, and the like. The touch screen layer may be a pressure-sensitive touch screen layer, a capacitive touch screen layer, and/or an infrared touch screen layer. The authentication apparatus may be, for example, a biometric authentication apparatus that authenticates an individual by using biometric information of a living body (for example, fingertips, pupils, and/or the like).

The authentication apparatus may further include, in addition to the light-emitting device as described above, a biometric information collector.

The electronic device may be applied to various suitable displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, and/or endoscope displays), fish finders, various suitable measuring instruments, meters (for example, meters for a vehicle, an aircraft, and/or a vessel), projectors, and/or the like.

### Electronic Apparatus

The light-emitting device may be included in various suitable electronic apparatuses.

For example, the electronic apparatus including the light-emitting device may be one selected from among a flat panel display, a curved display, a computer monitor, a medical monitor, a television, a billboard, an indoor light, an outdoor light, a signal light, a head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality display, an augmented reality display, a vehicle, a video wall including a plurality of displays tiled together, a theater screen, a stadium screen, a phototherapy device, and a signboard.

The light-emitting device may have excellent luminescence efficiency and long lifetime, and thus, the electronic apparatus including the light-emitting device may have characteristics such as high luminance, high resolution, and low power consumption.

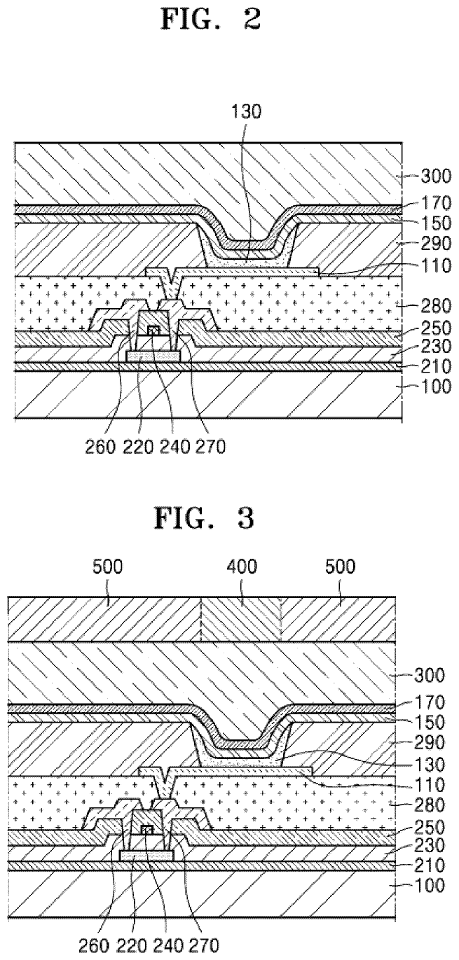

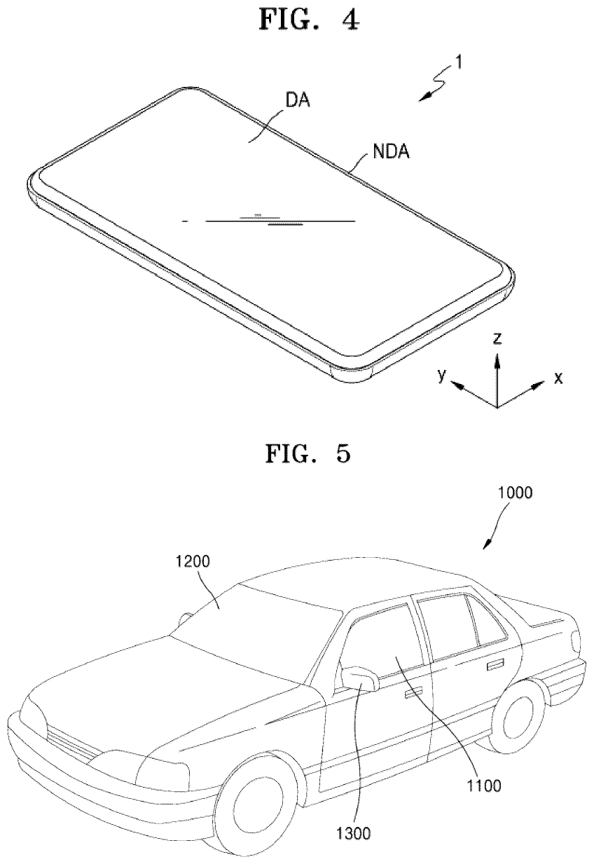

### Description of FIGS. 2 and 3

FIG. 2 is a schematic cross-sectional view of a structure of a light-emitting device which is one embodiment of an electronic device.

The light-emitting apparatus of FIG. 2 includes a substrate 100, a thin-film transistor (TFT), a light-emitting device, and an encapsulation portion 300 that seals the light-emitting device.

The substrate 100 may be a flexible substrate, a glass substrate, and/or a metal substrate. A buffer layer 210 may be on the substrate 100. The buffer layer 210 may prevent or reduce penetration of impurities through the substrate 100 and may provide a flat surface on the substrate 100.

A TFT may be on the buffer layer 210. The TFT may include an active layer 220, a gate electrode 240, a source electrode 260, and a drain electrode 270.

The active layer 220 may include an inorganic semiconductor such as silicon or polysilicon, an organic semiconductor, or an oxide semiconductor, and may include a source region, a drain region, and a channel region.

A gate insulating film 230 for insulating (e.g., electrically insulating) the active layer 220 from the gate electrode 240 may be on the active layer 220, and the gate electrode 240 may be on the gate insulating film 230.

An interlayer insulating film 250 may be on the gate electrode 240. The interlayer insulating film 250 may be between the gate electrode 240 and the source electrode 260 and between the gate electrode 240 and the drain electrode 270, to insulate (e.g., electrically insulate) from one another.

The source electrode 260 and the drain electrode 270 may be on the interlayer insulating film 250. The interlayer insulating film 250 and the gate insulating film 230 may expose the source region and the drain region of the active layer 220, and the source electrode 260 and the drain electrode 270 may be in contact (e.g., physical contact) with the exposed portions of the source region and the drain region of the active layer 220.

The TFT may be electrically connected to a light-emitting device to drive the light-emitting device, and may be covered and protected by a passivation layer 280. The passivation layer 280 may include an inorganic insulating film, an organic insulating film, or any combination thereof. The light-emitting device may be provided on the passivation layer 280. The light-emitting device may include a first electrode 110, an interlayer 130, and a second electrode 150.

The first electrode 110 may be on the passivation layer 280. The passivation layer 280 may expose a region of the drain electrode 270, not fully covering the drain electrode 270, and the first electrode 110 may be connected to the exposed portion of the drain electrode 270.

A pixel-defining film 290 including an insulating material (e.g., an electrically insulating material) may be on the first electrode 110. The pixel-defining film 290 may expose a region of the first electrode 110, and the interlayer 130 may be in the exposed region of the first electrode 110. The pixel-defining film 290 may be a polyimide-based organic film and/or a polyacrylic organic film. In embodiments, at least some layers of the interlayer 130 may extend beyond the upper portion of the pixel-defining film 290 to be provided in the form of a common layer.

A second electrode 150 may be on the interlayer 130, and a second capping layer 170 may be on the second electrode 150. The second capping layer 170 may cover the second electrode 150.

The encapsulation portion 300 may be on the second capping layer 170. The encapsulation portion 300 may be on a light-emitting device to protect the light-emitting device from moisture and/or oxygen. The encapsulation portion 300 may include: an inorganic film including silicon nitride (SiNx), silicon oxide (SiOx), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic-based resin (for example, polymethyl methacrylate, polyacrylic acid, and/or the like), an epoxy-based resin (for example, aliphatic glycidyl ether (AGE), and/or the like), or any combination thereof; or any combination of the inorganic film and the organic film.

FIG. 3 is a cross-sectional view schematically showing a structure of a light-emitting apparatus as one embodiment of an electronic device.

The light-emitting apparatus of FIG. 3 is the same as the light-emitting apparatus of FIG. 2, except that a light-shielding pattern 500 and a functional region 400 are on the encapsulation portion 300. The functional region 400 may be i) a color filter area, ii) a color conversion area, or iii) a combination of the color filter area and the color conversion area. According to an embodiment, the light-emitting device included in the light-emitting apparatus of FIG. 3 may be a tandem light-emitting device.

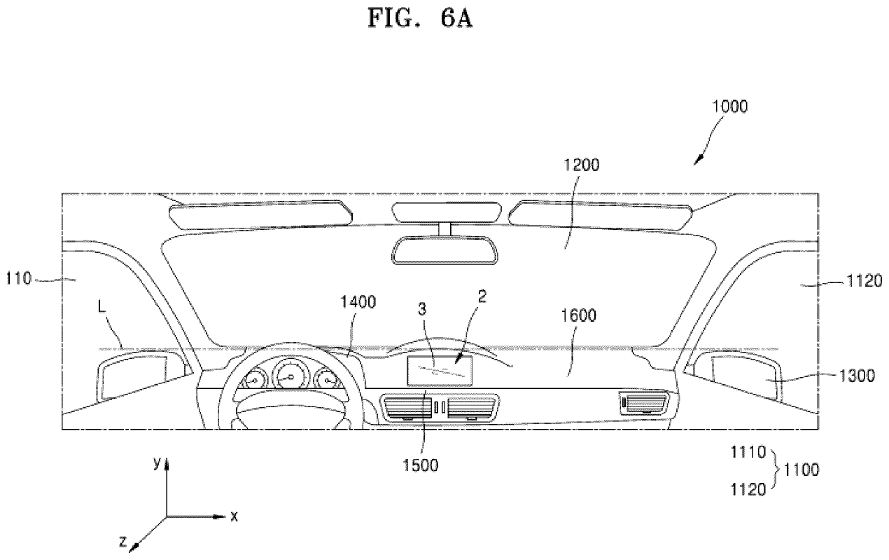

### Description of FIG. 4

FIG. 4 is a perspective view schematically showing an electronic apparatus 1 including a light-emitting device according to an embodiment. The electronic apparatus 1 may be, as an apparatus that displays a moving image and/or a still image, portable electronic apparatus, such as a mobile phone, a smartphone, a tablet personal computer (PC), a mobile communication terminal, an electronic notebook, an electronic book, a portable multimedia player (PMP), a navigation, and/or an ultra-mobile PC (UMPC), as well as various suitable products, such as a television, a laptop, a monitor, a billboard, and/or an Internet of things (IoT) device. The electronic apparatus 1 may be such a product above or a part thereof. In embodiments, the electronic apparatus 1 may be a wearable device, such as a smart watch, a watch phone, a glasses-type display, a head mounted display (HMD), and/or a part of the wearable device. However, embodiments are not limited thereto. For example, the electronic apparatus 1 may be a dashboard of a vehicle, a center information display (CID) on a center fascia and/or dashboard of a vehicle, a room mirror display instead of a side-view mirror of a vehicle, an entertainment system for the back seat of a vehicle, and/or a display on the back of the front seat of a vehicle, a head up display (HUD) installed on the front of a vehicle and/or projected on a front window glass, and/or a computer generated hologram augmented reality head up display (CGH AR HUD). FIG. 4 illustrates an embodiment in which the electronic equipment 1 is a smart phone for convenience of explanation, but the present disclosure is not limited thereto.

The electronic apparatus 1 may include a display area DA and a non-display area NDA outside the display area DA. A display device may implement or provide an image through an array of a plurality of pixels that are two-dimensionally provided in the display area DA.

The non-display area NDA is an area that does not display an image, and may entirely surround the display area DA. On the non-display area NDA, a driver to provide electrical signals and/or power to display devices on the display area DA may be provided. On the non-display area NDA, a pad, which is an area to which an electronic element and/or a printing circuit board may be electrically connected, may be provided.

In the electronic apparatus 1, a length in the x-axis direction and a length in the y-axis direction may be different from each other. For example, as shown in FIG. 4, the length in the x-axis direction may be shorter than the length in the y-axis direction. In one or more embodiments, the length in the x-axis direction may be the same as the length in the y-axis direction. In one or more embodiments, the length in the x-axis direction may be longer than the length in the y-axis direction.

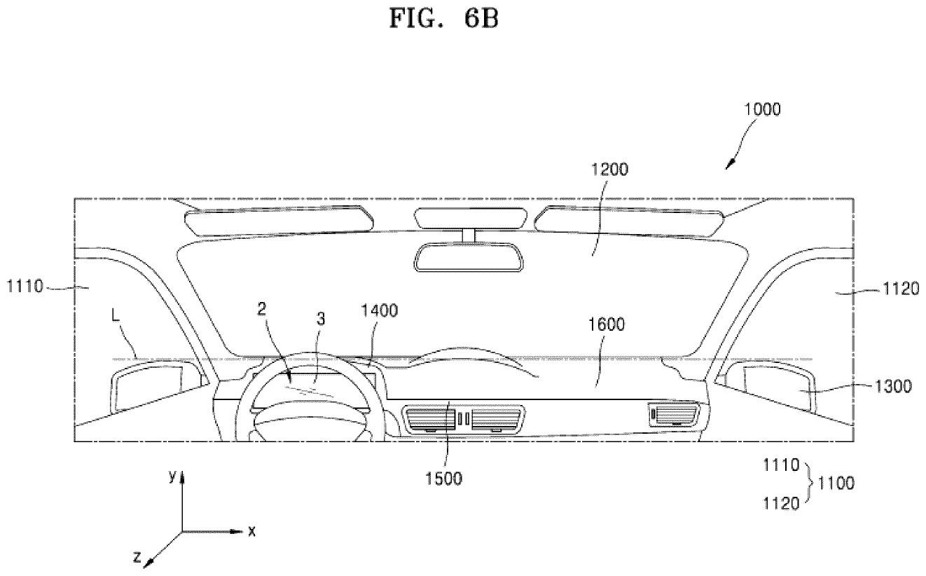

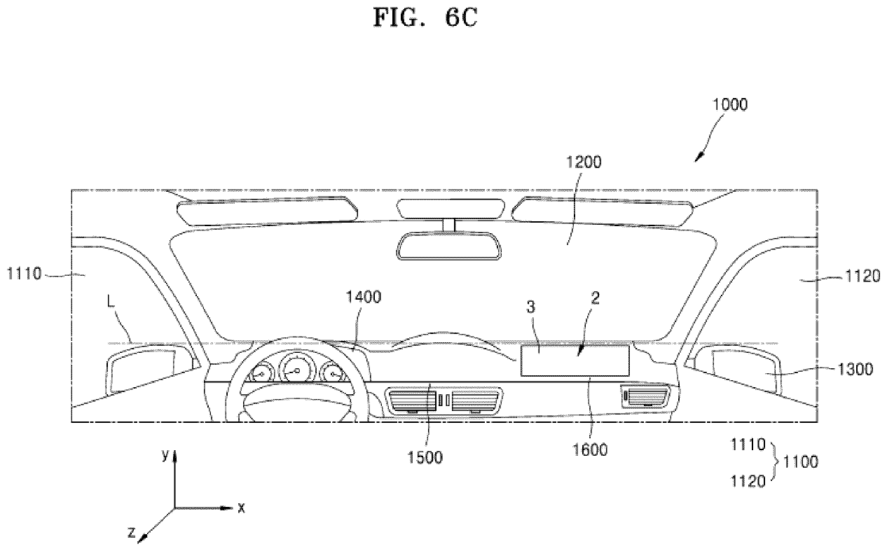

### Descriptions of FIGS. 5 and 6A to 6C

FIG. 5 is a schematic perspective view of the exterior of a vehicle 1000 as an electronic apparatus including the light-emitting device according to an embodiment. FIGS. 6A to 6C are each a schematic view of the interior of the vehicle 1000 according to one or more embodiments.

Referring to FIGS. 5, 6A, 6B, and 6C, the vehicle 1000 may refer to various suitable apparatuses for moving a subject object to be transported, such as a human, an object, and/or an animal, from a departure point to a destination. The vehicle 1000 may include a vehicle that travels on a road and/or track, a vessel that moves over a sea and/or river, an airplane that flies in the sky using the action of air, and/or the like.

The vehicle 1000 may travel on a road and/or a track. The vehicle 1000 may move in a certain direction according to rotation of at least one wheel. For example, the vehicle 1000 may include a three-wheeled or four-wheeled vehicle, a construction machine, a two-wheeled vehicle, a prime mover device, a bicycle, and/or a train that runs on a track.

The vehicle 1000 may include a body having an interior and an exterior, and a chassis in which mechanical apparatuses necessary or useful to drive are installed as other parts except for the body. The exterior of the body of the vehicle may include a front panel, a bonnet, a roof panel, a rear panel, a trunk, a pillar provided at a boundary between doors, and/or the like. The chassis of the vehicle 1000 may include a power generating device, a power transmitting device, a driving device, a steering device, a braking device, a suspension device, a transmission device, a fuel device, front and rear wheels, left and/or right wheels, and/or the like.

The vehicle 1000 may include a side window glass 1100, a front window glass 1200, a side mirror 1300, a cluster 1400, a center fascia 1500, a passenger seat dashboard 1600, and/or a display device 2.

The side window glass 1100 and the front window glass 1200 may be partitioned by a pillar between the side window glass 1100 and the front window glass 1200.

The side window glass 1100 may be installed on the side of the vehicle 1000. In an embodiment, the side window glass 1100 may be installed on a door of the vehicle 1000. A plurality of side window glasses 1100 may be provided and may face each other. In an embodiment, the side window glass 1100 may include a first side window glass 1110 and a second side window glass 1120. In an embodiment, the first side window glass 1110 may be adjacent to the cluster 1400. The second side window glass 1120 may be adjacent to the passenger seat dashboard 1600.

In an embodiment, the side window glasses 1100 may be spaced apart from each other in the +x direction or the −x direction. For example, the first side window glass 1110 and the second side window glass 1120 may be spaced apart from each other in the +x direction or the −x direction. In embodiments, an imaginary straight line L connecting the side window glasses 1100 may extend in the +x direction or the −x direction. For example, an imaginary straight line L connecting the first side window glass 1110 and the second side window glass 1120 to each other may extend in the +x direction or the −x direction.

The front window glass 1200 may be installed in the front of the vehicle 1000. The front window glass 1200 may be between the side window glasses 1100 facing each other.

The side mirror 1300 may provide a rear view of the vehicle 1000. The side mirror 1300 may be installed on the exterior of the body of the vehicle. According to an embodiment, a plurality of side mirrors 1300 may be provided. Any one of the plurality of side mirrors 1300 may be outside the first side window glass 1110. The other one of the plurality of side mirrors 1300 may be outside the second side window glass 1120.

The cluster 1400 may be in front of a steering wheel. The cluster 1400 may include a tachometer, a speedometer, a coolant thermometer, a fuel gauge, a turn signal indicator, a high beam indicator, a warning light, a seat belt warning light, an odometer, a tachograph (e.g., a tachometer), an automatic shift selector indicator lamp, a door open warning light, an engine oil warning light, and/or a low fuel warning light.

The center fascia 1500 may include a control panel on which a plurality of buttons to adjust an audio device, an air conditioning device, and/or a seat heater are provided. The center fascia 1500 may be on one side of the cluster 1400.

A passenger seat dashboard 1600 may be spaced apart from the cluster 1400, and the center fascia 1500 may be between the cluster 1400 and the passenger seat dashboard 1600. In an embodiment, the cluster 1400 may correspond to a driver seat, and the passenger seat dashboard 1600 may correspond to a passenger seat. According to an embodiment, the cluster 1400 may be adjacent to the first side window glass 1110, and the passenger seat dashboard 1600 may be adjacent to the second side window glass 1120.

In an embodiment, the display device 2 may include a display panel 3, and the display panel 3 may display an image. The display device 2 may be provided inside the vehicle 1000. In an embodiment, the display device 2 may be between the side window glasses 1100 facing each other. The display device 2 may be on at least one of the cluster 1400, the center fascia 1500, and the passenger seat dashboard 1600.

The display device 2 may include an organic light-emitting display, an inorganic electroluminescent (EL) display, a quantum dot display, and/or the like. Hereinafter, as the display device 2 according to an embodiment, an organic light-emitting display device including the light-emitting device will be described as an example, but various suitable types or kinds of display apparatuses as described above may be used in embodiments.

Referring to FIG. 6A, the display device 2 may be on the center fascia 1500. According to an embodiment, the display device 2 may display navigation information. According to an embodiment, the display device 2 may display information regarding audio settings, video setting, and/or vehicle settings.

Referring to FIG. 6B, the display device 2 may be on the cluster 1400. When the display device 2 is on the cluster 1400, the cluster 1400 may display driving information and/or the like through the display device 2. For example, the cluster 1400 may digitally implement driving information and/or the like. The cluster 1400 operated in the digital manner may display vehicle information and driving information in the form of images. For example, a needle and/or a gauge of a tachometer and/or various suitable warning light icons may be displayed by a digital signal.

Referring to FIG. 6C, the display device 2 may be on the dashboard 1600 of the passenger seat. The display device 2 may be embedded in the passenger seat dashboard 1600 and/or on the passenger seat dashboard 1600. According to an embodiment, the display device 2 on the passenger seat dashboard 1600 may display an image related to information displayed on the cluster 1400 and/or information displayed on the center fascia 1500. In one or more embodiments, the display device 2 arranged on the passenger seat dashboard 1600 may display information different from information displayed on the cluster 1400 and/or information displayed on the center fascia 1500.

### Manufacturing Method

Respective layers included in the hole transport region, the emission layer, and respective layers included in the electron transport region may be formed in a certain region by using one or more suitable methods selected from among vacuum deposition, spin coating, casting, Langmuir-Blodgett (LB) deposition, ink-jet printing, laser-printing, laser-induced thermal imaging, and the like.

When respective layers included in the hole transport region, the emission layer, and respective layers included in the electron transport region are formed by vacuum deposition, the deposition may be performed at a deposition temperature of about 100° C. to about 500° C., a vacuum degree of about 10⁻⁸ torr to about 10⁻³ torr, and a deposition speed of about 0.01 Å/sec to about 100 Å/sec, depending on the material to be included in a layer to be formed and the structure of a layer to be formed.

### Definition of Terms

The term “C₃-C₆₀ carbocyclic group” as used herein refers to a cyclic group consisting of carbon only as a ring-forming atom and having 3 to 60 carbon atoms (for example, 3 to 30, 3 to 20, 3 to 15, or 3 to 10 carbon atoms), and the term “C₁-C₆₀ heterocyclic group” as used herein refers to a cyclic group that has 1 to 60 carbon atoms (for example, 1 to 30, 1 to 20, 1 to 15, or 1 to 10 carbon atoms) and further has, in addition to carbon, a heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. For example, the C₁-C₆₀ heterocyclic group has 3 to 61 ring-forming atoms (for example, 3 to 30, 3 to 20, 3 to 15, or 3 to 10 ring-forming atoms).

The term “cyclic group” as used herein may include both the C₃-C₆₀ carbocyclic group and the C₁-C₆₀ heterocyclic group.

The term “π electron-rich C₃-C₆₀ cyclic group” as used herein refers to a cyclic group that has 3 to 60 carbon atoms (for example, 3 to 30, 3 to 20, 3 to 15, or 3 to 10 carbon atoms) and does not include *—N═*′ as a ring-forming moiety, and the term “π electron-deficient nitrogen-containing C₁-C₆₀ heterocyclic group” as used herein refers to a heterocyclic group that has 1 to 60 carbon atoms (for example, 1 to 30, 1 to 20, 1 to 15, or 1 to 10 carbon atoms) and includes *—N═*′ as a ring-forming moiety.

For example,
the C₃-C₆₀ carbocyclic group may be i) Group T1 or ii) a condensed cyclic group in which two or more of Group T1 are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) Group T2, ii) a condensed cyclic group in which two or more of Group T2 are condensed with each other, or iii) a condensed cyclic group in which at least one Group T2 and at least one Group T1 are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
the π electron-rich C₃-C₆₀ cyclic group may be i) Group T1, ii) a condensed cyclic group in which two or more of Group T1 are condensed with each other, iii) Group T3, iv) a condensed cyclic group in which two or more of Group T3 are condensed with each other, or v) a condensed cyclic group in which at least one Group T3 and at least one Group T1 are condensed with each other (for example, the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.),
the π electron-deficient nitrogen-containing C₁-C₆₀ heterocyclic group may be i) Group T4, ii) a condensed cyclic group in which two or more of Group T4 are condensed with each other, iii) a condensed cyclic group in which at least one Group T4 and at least one Group T1 are condensed with each other, iv) a condensed cyclic group in which at least one Group T4 and at least one Group T3 are condensed with each other, or v) a condensed cyclic group in which at least one Group T4, at least one Group T1, and at least one Group T3 are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
Group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
Group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
Group T3 may be a furan group, a thiophene group, a 1H-pyrrole group, a silole group, or a borole group, and
Group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “the cyclic group”, “the C₃-C₆₀ carbocyclic group”, “the C₁-C₆₀ heterocyclic group”, “the π electron-rich C₃-C₆₀ cyclic group”, and “the π electron-deficient nitrogen-containing C₁-C₆₀ heterocyclic group” as used herein may each refer to a group condensed to any suitable cyclic group, a monovalent group, or a polyvalent group (for example, a divalent group, a trivalent group, a tetravalent group, etc.) according to the structure of a formula for which the corresponding term is used. For example, “a benzene group” may be a benzo group, a phenyl group, a phenylene group, or the like, which may be easily understand by one of ordinary skill in the art according to the structure of a formula including the “benzene group.”

Examples of the monovalent C₃-C₆₀ carbocyclic group and the monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group. Examples of the divalent C₃-C₆₀ carbocyclic group and the monovalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a substituted or unsubstituted divalent non-aromatic condensed heteropolycyclic group.

The term “C₁-C₆₀ alkyl group” as used herein refers to a linear or branched aliphatic hydrocarbon monovalent group that has 1 to 60 carbon atoms (for example, 1 to 30, 1 to 20, 1 to 15, or 1 to 10 carbon atoms), and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, and the like. The term “C₁-C₆₀ alkylene group” as used herein refers to a divalent group having substantially the same structure as the C₁-C₆₀ alkyl group.

The term “C₂-C₆₀ alkenyl group” as used herein refers to a monovalent hydrocarbon group having at least one double bond at a main chain (e.g., in the middle) or at a terminal end (e.g., the terminus) of the C₂-C₆₀ alkyl group, and examples thereof may include an ethenyl group, a propenyl group, a butenyl group, and the like. The term “C₂-C₆₀ alkenylene group” as used herein refers to a divalent group having substantially the same structure as the C₂-C₆₀ alkenyl group.

The term “C₂-C₆₀ alkynyl group” as used herein refers to a monovalent hydrocarbon group having at least one triple bond at a main chain (e.g., in the middle) or at a terminal end (e.g., the terminus) of the C₂-C₆₀ alkyl group, and examples thereof may include an ethynyl group, a propynyl group, and the like. The term “C₂-C₆₀ alkynylene group” as used herein refers to a divalent group having substantially the same structure as the C₂-C₆₀ alkynyl group.

The term “C₁-C₆₀ alkoxy group” as used herein refers to a monovalent group represented by —OA₁₀₁ (wherein A₁₀₁ is the C₁-C₆₀ alkyl group), and examples thereof may include a methoxy group, an ethoxy group, an isopropyloxy group, and the like.

The term “C₃-C₁₀ cycloalkyl group” as used herein refers to a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, and the like. The term “C₃-C₁₀ cycloalkylene group” as used herein refers to a divalent group having substantially the same structure as the C₃-C₁ cycloalkyl group.

The term “C₁-C₁₀ heterocycloalkyl group” as used herein refers to a monovalent cyclic group having 1 to 10 carbon atoms, and further including, in addition to carbon atoms, at least one heteroatom, as ring-forming atoms, and examples thereof may include a 1,2,3,4-oxatriazolidinyl group, a tetrahydrofuranyl group, a tetrahydrothiophenyl group, and the like. The term “C₁-C₁₀ heterocycloalkylene group” as used herein refers to a divalent group having substantially the same structure as the C₁-C₁₀ heterocycloalkyl group.

The term “C₃-C₁₀ cycloalkenyl group” as used herein refers to a monovalent cyclic group that has 3 to 10 carbon atoms, at least one double bond in the ring thereof, and no aromaticity (e.g., is not aromatic), and examples thereof may include a cyclopentenyl group, a cyclohexenyl group, a cycloheptenyl group, and the like. The term “C₃-C₁₀ cycloalkenylene group” as used herein refers to a divalent group having substantially the same structure as the C₃-C₁₀ cycloalkenyl group.

The term “C₁-C₁₀ heterocycloalkenyl group” as used herein refers to a monovalent cyclic group of 1 to 10 carbon atoms, further including, in addition to carbon atoms, at least one heteroatom, as ring-forming atoms, and having at least one double bond in the cyclic structure thereof. Examples of the C₁-C₁₀ heterocycloalkenyl group may include a 4,5-dihydro-1,2,3,4-oxatriazolyl group, a 2,3-dihydrofuranyl group, a 2,3-dihydrothiophenyl group, and the like. The term “C₁-C₁₀ heterocycloalkenylene group” as used herein refers to a divalent group having substantially the same structure as the C₁-C₁₀ heterocycloalkenyl group.

The term “C₆-C₆₀ aryl group” as used herein refers to a monovalent group having a carbocyclic aromatic system of 6 to 60 carbon atoms (for example, 6 to 30, 6 to 20, 6 to 15, or 6 to 10 carbon atoms), and the term “C₆-C₆₀ arylene group” as used herein refers to a divalent group having a carbocyclic aromatic system of 6 to 60 carbon atoms (for example, 6 to 30, 6 to 20, 6 to 15, or 6 to 10 carbon atoms). Examples of the C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and the like. When the C₆-C₆₀ aryl group and the C₆-C₆₀ arylene group each include two or more rings, the rings may be condensed with each other.

The term “C₁-C₆₀ heteroaryl group” as used herein refers to a monovalent group having a heterocyclic aromatic system of 1 to 60 carbon atoms (for example, 1 to 30, 1 to 20, 1 to 15, or 1 to 10 carbon atoms), and further including, in addition to carbon atoms, at least one heteroatom, as ring-forming atoms. The term “C₁-C₆₀ heteroarylene group” as used herein refers to a divalent group having a heterocyclic aromatic system of 1 to 60 carbon atoms (for example, 1 to 30, 1 to 20, 1 to 15, or 1 to 10 carbon atoms), and further including, in addition to carbon atoms, at least one heteroatom, as ring-forming atoms. Examples of the C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and the like. When the C₁-C₆₀ heteroaryl group and the C₁-C₆₀ heteroarylene group each include two or more rings, the rings may be condensed with each other.

The term “monovalent non-aromatic condensed polycyclic group” as used herein refers to a monovalent group (for example, having 8 to 60 carbon atoms, such as 8 to 30, 8 to 20, 8 to 15, or 8 to 10 carbon atoms) having two or more rings condensed to each other, only carbon atoms as ring-forming atoms, and no aromaticity in its entire molecular structure (e.g., is not aromatic when considered as a whole). Examples of the monovalent non-aromatic condensed polycyclic group may include an indenyl group, a fluorenyl group, a spiro-bifluorenyl group, a benzofluorenyl group, an indenophenanthrenyl group, an indeno anthracenyl group, and the like. The term “divalent non-aromatic condensed polycyclic group” as used herein refers to a divalent group having substantially the same structure as the monovalent non-aromatic condensed polycyclic group described above.

The term “monovalent non-aromatic condensed heteropolycyclic group” as used herein refers to a monovalent group (for example, having 1 to 60 carbon atoms, such as 1 to 30, 1 to 20, 1 to 15, or 1 to 10 carbon atoms) having two or more rings condensed to each other, further including, in addition to carbon atoms, at least one heteroatom, as ring-forming atoms, and having no aromaticity in its entire molecular structure (e.g., is not aromatic when considered as a whole). Examples of the monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, a benzothienodibenzothiophenyl group, and the like. The term “divalent non-aromatic condensed heteropolycyclic group” as used herein refers to a divalent group having substantially the same structure as the monovalent non-aromatic condensed heteropolycyclic group described above.

The term “C₆-C₆₀ aryloxy group” as used herein indicates —OA₁₀₂ (wherein A₁₀₂ is the C₆-C₆₀ aryl group), and the term “C₆-C₆₀ arylthio group” as used herein indicates —SA₁₀₃ (wherein A₁₀₃ is the C₆-C₆₀ aryl group).

The term “C₇-C₆₀ arylalkyl group” as used herein refers to -A₁₀₄A₁₀₅ (wherein A₁₀₄ is a C₁-C₅₄ alkylene group, and A₁₀₅ is a C₆-C₅₉ aryl group), and the term “C₂-C₆₀ heteroarylalkyl group” as used herein refers to -A₁₀₆A₁₀₇ (wherein A₁₀₆ is a C₁-C₅₉ alkylene group, and A₁₀₇ is a C₁-C₅₉ heteroaryl group).

The term “R₁₀ₐ” as used herein refers to:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

Q₁ to Q₃, Q₁₁ to Q₁₃, Q₂₁ to Q₂₃, and Q₃₁ to Q₃₃ used herein may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ aryl alkyl group; or a C₂-C₆₀ heteroaryl alkyl group.

The term “heteroatom” as used herein refers to any atom other than a carbon atom, and the number of the heteroatom may be 1 to 10, for example 1, 2, 3, 4, or 5. Examples of the heteroatom may include O, S, N, P, Si, B, Ge, Se, and any combination thereof.

The term “transition metal” as used herein may include hafnium (Hf), tantalum (Ta), tungsten (W), rhenium (Re), osmium (Os), iridium (Ir), platinum (Pt), and gold (Au).

The term “Ph” as used herein refers to a phenyl group, the term “Me” as used herein refers to a methyl group, the term “Et” as used herein refers to an ethyl group, the term “ter-Bu” or “Bu^{t}” as used herein refers to a tert-butyl group, and the term “OMe” as used herein refers to a methoxy group.

The term “biphenyl group” as used herein refers to “a phenyl group substituted with a phenyl group.” The “biphenyl group” may be “a substituted phenyl group” having “a C₆-C₆₀ aryl group” as a substituent.

The term “terphenyl group” as used herein refers to “a phenyl group substituted with a biphenyl group”. The “terphenyl group” may be “a substituted phenyl group” having, as a substituent, “a C₆-C₆₀ aryl group that is substituted with a C₆-C₆₀ aryl group.”

* and *′ as used herein, unless defined otherwise, each refer to a binding site to a neighboring atom in a corresponding formula or moiety.

In the specification, the terms “x-axis”, “y-axis”, and “z-axis” are not limited to three axes in an orthogonal coordinate system, and may be interpreted in a broader sense than the aforementioned three axes in an orthogonal coordinate system. For example, the x-axis, y-axis, and z-axis may describe axes that are orthogonal to each other, or may describe axes that are in different directions that are not orthogonal to each other.

Hereinafter, a composition and a light-emitting device according to an embodiment will be described in more detail with reference to the following Examples.

### EXAMPLES

### Experimental Example 1

A composition of CdSe quantum dots in an octane solvent (a quantum dot concentration of 50 mg/mL) was prepared.

### Experimental Example 2

Ethanol was added at a ratio of 3:1 (v:v) to a CdSe quantum dot octane solution (a quantum dot concentration of 50 mg/mL) to precipitate the quantum dots and the quantum dots were purified by centrifugation. The purified CdSe quantum dots were redispersed in an octane solvent (a quantum dot concentration of 50 mg/mL).

### Experimental Example 3

CdSe quantum dots were purified by using substantially the same method as in Experimental Example 2, except that a mixed solution of Polymer compound 1 (a weight average molecular weight of 25,000) and ethanol (a polymer concentration of 0.5 wt % of the weight of the quantum dots) was used instead of ethanol. The purified CdSe quantum dots were redispersed in an octane solvent (a quantum dot concentration of 50 mg/mL).

### Experimental Example 4

CdSe quantum dots were purified by using a mixed solution of Polymer compound 1 and ethanol in substantially the same manner as in Experimental Example 3, and the purified CdSe quantum dots were dispersed in a cyclohexylbenzene solvent to manufacture a quantum dot composition (a quantum dot concentration of 50 mg/mL).

### Experimental Example 5

CdSe quantum dots purified in substantially the same manner as in Experimental Example 2 were dispersed in a cyclohexylbenzene solvent including Polymer compound 1 (a polymer concentration of 0.5 wt % of the weight of quantum dots) to manufacture a quantum dot composition (a quantum dot concentration of 50 mg/mL).

### Experimental Example 6

A quantum dot composition having quantum dots dispersed therein was manufactured in substantially the same manner as in Experimental Example 5, except that Polymer compound 2 was used instead of Polymer compound 1.

### Experimental Example 7

A quantum dot composition was manufactured in substantially the same manner as in Experimental Example 5, except that Polymer compound 3 was used instead of Polymer compound 1.

### Experimental Example 8

A quantum dot composition was manufactured in substantially the same manner as in Experimental Example 5, except that Polymer compound 4 was used instead of Polymer compound 1.

### Experimental Example 9

A quantum dot composition was manufactured in substantially the same manner as in Experimental Example 3, except that polyethylene glycol (a weight average molecular weight of 50,000) was used instead of Polymer compound 1 during the purification of quantum dots.

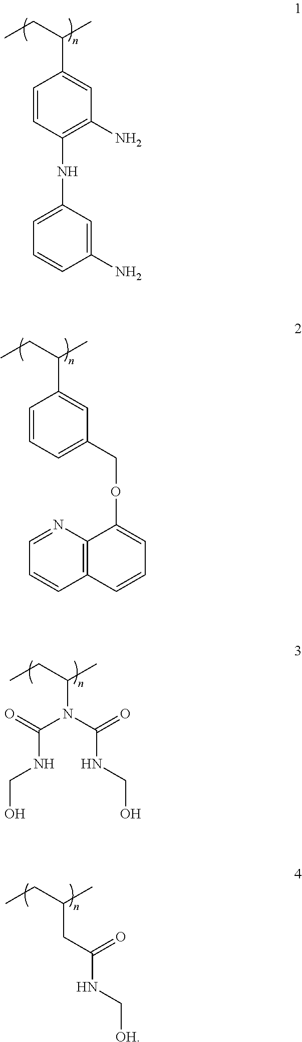

### Measurement of Cadmium Ion Concentration

The concentration of cadmium ions (Cd²⁺) in each of the quantum dot compositions of Experimental Examples 1 to 9 was measured by using ion chromatography, and the results are shown in Table 1.

TABLE 1

| | | Solvent for finally | |
|---|---|---|---|
| | Solvent for purifying | dispersing quantum | Cadmium ion (Cd²⁺) |
| | quantum dots | dots | concentration (ppm) |
| Experimental | Non-purified | Octane | 200 |
| Example 1 | | | |
| Experimental | Ethanol | Octane | 198 |
| Example 2 | | | |
| Experimental | Ethanol + Polymer | Octane | 0 |
| Example 3 | compound 1 | | |
| Experimental | Ethanol + Polymer | Cyclohexylbenzene | 0 |
| Example 4 | compound 1 | | |
| Experimental | Ethanol | Cyclohexylbenzene + | 0 |
| Example 5 | | Polymer compound 1 | |
| Experimental | Ethanol | Cyclohexylbenzene + | 0 |
| Example 6 | | Polymer compound 2 | |
| Experimental | Ethanol | Cyclohexylbenzene + | 0 |
| Example 7 | | Polymer compound 3 | |
| Experimental | Ethanol | Cyclohexylbenzene + | 0 |
| Example 8 | | Polymer compound 4 | |
| Experimental | Ethanol + Polyethylene | Octane | 190 |
| Example 9 | Glycol | | |

Referring to Table 1, the concentration of cadmium ions in the composition of Experimental Example 2, in which CdSe quantum dots were purified with ethanol and then redispersed in octane, was measured to be 198 ppm, which is a similar value to the concentration of cadmium ions in octane before purifying the CdSe quantum dots, which is 200 ppm. On the other hand, in the composition of Experimental Example 3 in which CdSe quantum dots were purified with a mixed solution of ethanol and Polymer compound 1 and then redispersed in octane, no cadmium ions were detected. Also, in the composition of Experimental Example 4 in which CdSe quantum dots were purified in substantially the same manner as in Experimental Example 3 and then dispersed in cyclohexylbenzene, no cadmium ions were detected. Additionally, no cadmium ions were detected in the CdSe quantum dot compositions of Experimental Examples 5 to 8 including any one of Polymer compounds 1 to 4 according to the embodiments. From this, it was determined that Polymer compounds 1 to 4 effectively adsorb and remove cadmium ions in the solvent.

Meanwhile, cadmium ions were detected in the CdSe quantum dot composition of Experimental Example 9, which included polyethylene glycol instead of the polymers according to the embodiment, in a solvent for purifying quantum dots.

### Experimental Example 10

CdSe quantum dots washed with ethanol were dispersed in a cyclohexylbenzene solvent to form a CdSe quantum dot composition (a quantum dot concentration of 50 mg/mL), and then, the CdSe quantum dot composition was inkjet-printed to form a CdSe quantum dot layer having a thickness of 500 Å.

### Experimental Example 11

CdSe quantum dots washed with ethanol were dispersed in a cyclohexylbenzene solvent to form a CdSe quantum dot composition (a quantum dot concentration of 50 mg/mL), and then, CdSe quantum dot composition was inkjet-printed to form a CdSe quantum dot layer having a thickness of 500 Å. A composition consisting of a tripropylene glycol monomethyl ether solvent including ZnMgO nanoparticles (a nanoparticle concentration of 15 mg/mL) was inkjet-printed on the CdSe quantum dot layer to form a ZnMgO nanoparticle layer having a thickness of 480 Å.

### Experimental Example 12

CdSe quantum dots washed with ethanol were dispersed in a cyclohexylbenzene solvent to form a CdSe quantum dot composition (a quantum dot concentration of 50 mg/mL), and then, the CdSe quantum dot composition was inkjet-printed to form a CdSe quantum dot layer having a thickness of 500 Å. A composition consisting of a tripropylene glycol monomethyl ether solvent including ZnMgO nanoparticles and Polymer compound 1 (a ZnMgO nanoparticle concentration of 15 mg/mL, a Polymer compound 1 concentration of 0.1 wt % based on the weight of ZnMgO nanoparticles) was inkjet-printed on the CdSe quantum dot layer to form a polymer+ZnMgO nanoparticle layer having a thickness of 480 Å.

### Experimental Example 13

CdSe quantum dots washed with ethanol were dispersed in a cyclohexylbenzene solvent to form a CdSe quantum dot composition (a quantum dot concentration of 50 mg/mL), and then, the CdSe quantum dot composition was inkjet-printed to form a CdSe quantum dot layer having a thickness of 500 Å. A tripropylene glycol monomethyl ether solvent including Polymer compound 1 (1 wt % of Polymer compound 1 based on the weight of the solvent) was spin-coated on the CdSe quantum dot layer to form a polymer layer. A composition consisting of a tripropylene glycol monomethyl ether solvent including ZnMgO nanoparticles (a nanoparticle concentration of 15 mg/mL) was inkjet-printed on the polymer layer to form a ZnMgO nanoparticle layer having a thickness of 480 Å.

The photoluminescence quantum yield (PLQY) of thin films respectively including the quantum dot layers manufactured in Experimental Examples 10 to 13 was measured by using a QE-2100 device, and the results are shown in Table 2. When measuring the PLQY, an excitation wavelength of 450 nm and a measurement wavelength of 535 nm to 536 nm were used, and the measurements were performed at room temperature (25° C.).

TABLE 2

| | Layered structure | PLQY (%) |
|---|---|---|
| Experimental | CdSe quantum dot layer | 99 |
| Example 10 | | |
| Experimental | CdSe quantum dot layer/ZnMgO nanoparticle | 65 |
| Example 11 | layer | |
| Experimental | CdSe quantum dot layer/polymer + ZnMgO | 97 |
| Example 12 | nanoparticle layer | |
| Experimental | CdSe quantum dot layer/polymer layer/ZnMgO | 98 |
| Example 13 | nanoparticle layer | |

Referring to Table 2, the PLQY of Experimental Example 11, in which a ZnMgO nanoparticle layer not including Polymer compound 1 was formed on a CdSe quantum dot layer, was lower by 30% or more than the PLQY of Experimental Example 10, which only included a CdSe quantum dot layer. While the present disclosure is not limited to any particular mechanism or theory, this is thought to be due to the quenching of the luminescence of CdSe quantum dots by the oxygen vacancy of ZnMgO nanoparticles. On the other hand, the PLQY of Experimental Example 12, in which a ZnMgO nanoparticle layer including Polymer compound 1 was formed on a CdSe quantum dot layer, was shown to be comparable to the PLQY of Experimental Example 10, which only included a CdSe quantum dot layer. In addition, the PLQY of Experimental Example 13, in which a polymer layer consisting of Polymer compound 1 was formed on a CdSe quantum dot layer and then a ZnMgO nanoparticle layer was formed thereon, was shown to be comparable to the PLQY of Experimental Example 10. While the present disclosure is not limited to any particular mechanism or theory, this is thought to be due to the prevention or reduction of a direct contact between CdSe quantum dots and ZnMgO nanoparticles by the polymer layer on the quantum dot layer and/or Polymer compound 1 in the ZnMgO nanoparticle layer, and accordingly, the prevention or reduction of the quenching of the luminescence of CdSe quantum dots.

### Example 1

As an anode electrode, a Corning 15 Ω/cm² (1,200 Å) ITO glass substrate was cut to a size of 50 mm×50 mm×0.7 mm, sonicated with isopropyl alcohol and pure water each for 5 minutes, cleaned by exposure to ultraviolet rays and ozone for 30 minutes, and then dried. PEDOT/PSS was spin-coated on the substrate to form a hole injection layer having a thickness of 1350 Å. Subsequently, poly(9,9-dioctylfluorene-alt-N-(4-sec-butylphenyl)-diphenylamine) (TFB) was spin-coated to form a hole transport layer having a thickness of 400 Å. A CdSe quantum dot composition (dispersed in cyclohexyl benzene, a concentration of 50 mg/mL) was inkjet-printed on the hole transport layer to form an emission layer having a thickness of 500 Å. A composition including ZnMgO nanoparticles and Polymer compound 1 dispersed in tripropylene glycol monomethyl ether (a nanoparticle concentration of 15 mg/mL, a polymer concentration of 0.1 wt % based on the weight of ZnMgO nanoparticles) was inkjet-printed on the emission layer to form an electron transport layer having a thickness of 480 Å. AgMg was vacuum-deposited on the electron transport layer to a thickness of 200 Å to form a cathode electrode, thereby completing the manufacture of a light-emitting device.

### Example 2 (Polymer Compound 1/ZnMgO)

A light-emitting device was manufactured in substantially the same manner as in Example 1, except that a tripropylene glycol monomethyl ether having Polymer compound 1 dispersed therein (1 wt % of Polymer compound 1 based on the weight of the solvent) was spin-coated onto the emission layer to form a polymer layer having a thickness of 100 Å, and then, a composition consisting of a tripropylene glycol monomethyl ether having ZnMgO nanoparticles dispersed therein (a nanoparticle concentration of 15 mg/mL) was inkjet-printed on the polymer layer to form an electron transport layer having a thickness of 480 Å.

### Comparative Example 1 (ZnMgO)

A light-emitting device was manufactured in substantially the same manner as in Example 1, except that when forming an electron transport layer, a composition consisting of tripropylene glycol monomethyl ether having ZnMgO nanoparticles dispersed therein (a nanoparticle concentration of 15 mg/mL) was inkjet-printed on the emission layer to form an electron transport layer having a thickness of 480 Å.

The current efficiency of each of the light-emitting devices of Example 1, Example 2, and Comparative Example 1 was measured by using an I-V-L measuring device (M6100, McScience), and the results are shown in Table 3.

TABLE 3

| | | Current |
|---|---|---|
| | | efficiency |
| | | (cd/A) |
| Example 1 | CdSe quantum dot layer/polymer + ZnMgO | 72 |
| | nanoparticle layer | |
| Example 2 | CdSe quantum dot layer/polymer layer/ZnMgO | 70 |
| | nanoparticle layer | |
| Comparative | CdSe quantum dot layer/ZnMgO nanoparticle | 50 |
| Example 1 | layer | |

Referring to Table 3, the light-emitting device of Example 1, in which the electron transport layer includes Polymer compound 1, and the light-emitting device of Example 2, in which the polymer layer composed of Polymer compound 1 on the quantum dot emission layer is included, exhibit current efficiency that is 20 cd/A or more higher than that of Comparative Example 1, in which the electron transport layer does not include Polymer compound 1. It is believed that in the case of Examples 1 and 2, the quenching of quantum dot luminescence by the electron transport layer was reduced, thereby improving the current efficiency of the light-emitting device.

By forming an electron transport layer from the metal oxide nanoparticle composition, it is possible to trap metal ions originating from the quantum dot emission layer to reduce the leakage of the metal ions to the outside of a panel and suppress quenching phenomenon of the quantum dot emission layer, thereby improving the luminescence efficiency of the light-emitting device.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various suitable changes in form and details may be made therein without departing from the spirit and scope as defined by the following claims, and equivalents thereof.

What is claimed is:

1. A metal oxide nanoparticle composition comprising:
metal oxide nanoparticles;
a polymer comprising a moiety represented by Formula 1; and
a solvent,
wherein an amount of the polymer is about 0.1 wt % to about 1 wt % of a weight of the metal oxide nanoparticles: 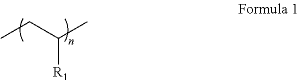
wherein, in Formula 1, R₁ is a functional group comprising two or more electron donor atoms, and n is an integer from 100 to 500.

2. The metal oxide nanoparticle composition of claim 1,
wherein the electron donor atom comprises nitrogen (N) or oxygen (O).

3. The metal oxide nanoparticle composition of claim 1,
wherein the functional groups R₁ each independently comprise one selected from among Structures 1 to 4 below:

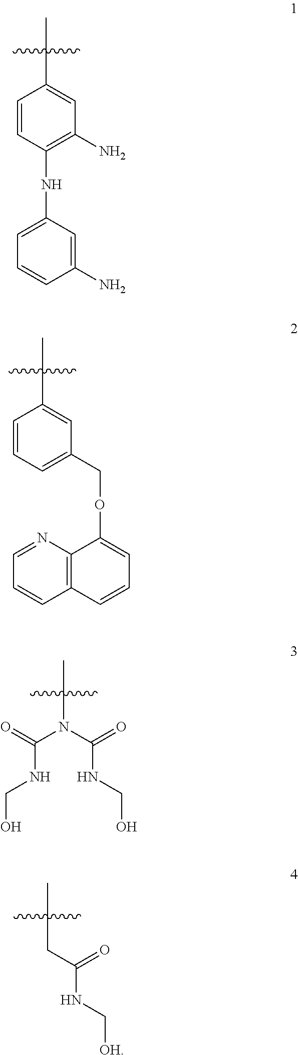 [SMILES: *c1ccc(Nc2cccc(N)c2)c(N)c1 ; *c1cccc(COc2cccc3cccnc23)c1 ; *N(C(=O)NCO)C(=O)NCO ; *CC(=O)NCO]

4. The metal oxide nanoparticle composition of claim 1,
wherein the metal oxide nanoparticles comprise:
ZnO, ZnMgO, ZnMgO:Sn, ZnSnO, ZnAlO, SnO₂, TiO₂, or any combination thereof.

5. A light-emitting device comprising:
an anode;
a cathode facing the anode; and
an interlayer comprising an emission layer and an electron transport region, wherein the emission layer is between the anode and the cathode, and the electron transport region is between the emission layer and the cathode,
wherein the electron transport region comprises: metal oxide nanoparticles; and
a polymer comprising a moiety represented by Formula 1,
wherein an amount of the polymer is about 0.1 wt % to about 1 wt % of a weight of the metal oxide nanoparticles: 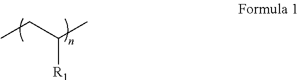
wherein, in Formula 1, R₁ is a functional group comprising two or more electron donor atoms, and n is an integer from 100 to 500.

6. The light-emitting device of claim 5,
wherein the electron transport region comprises an electron transport layer, and
the electron transport layer comprises the metal oxide nanoparticles and the polymer.

7. The light-emitting device of claim 6,
wherein the electron transport layer and the emission layer are in contact with each other.

8. A light-emitting device comprising:
an anode;
a cathode facing the anode; and
an interlayer comprising an emission layer and an electron transport region, wherein the emission layer is between the anode and the cathode, and the electron transport region is between the emission layer and the cathode,
wherein the electron transport region comprises an electron transport layer and a polymer layer between the emission layer and the electron transport layer,
the electron transport layer comprises metal oxide nanoparticles, and
the polymer layer comprises a polymer including a moiety represented by Formula 1: 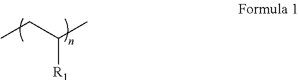
wherein, in Formula 1, R₁ is a functional group comprising two or more electron donor atoms, and n is an integer from 100 to 500.

9. The light-emitting device of claim 8,
wherein the polymer layer and the emission layer are in contact with each other.

10. The light-emitting device of claim 8,
wherein a thickness of the polymer layer is about 1 nm to about 10 nm.

11. The light-emitting device of claim 8,
wherein the electron donor atoms comprise N or O.

12. The light-emitting device of claim 8,
wherein the functional groups R₁ each independently comprise one of Structures 1 to 4 below:

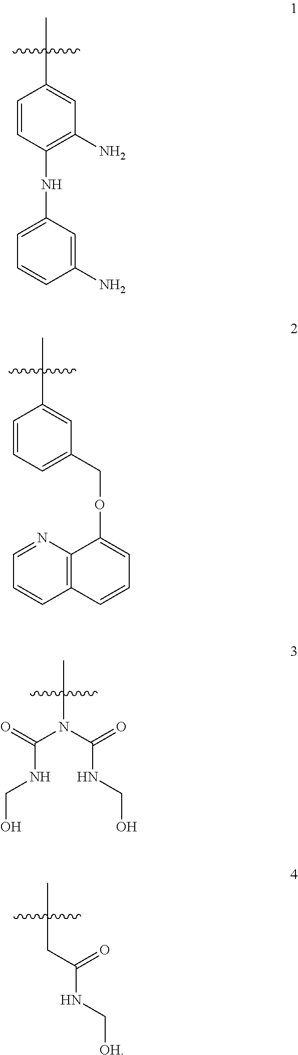 [SMILES: *c1ccc(Nc2cccc(N)c2)c(N)c1 ; *c1cccc(COc2cccc3cccnc23)c1 ; *N(C(=O)NCO)C(=O)NCO ; *CC(=O)NCO]

13. The light-emitting device of claim 8,
wherein the metal oxide nanoparticles comprise:
ZnO, ZnMgO, ZnMgO:Sn, ZnSnO, ZnAlO, SnO₂, TiO₂, or any combination thereof.

14. The light-emitting device of claim 8,
wherein the emission layer comprises quantum dots.

15. The light-emitting device of claim 14,
wherein the quantum dots comprise a Group II-IV semiconductor compound.

16. The light-emitting device of claim 15,
wherein the quantum dots comprise CdS, CdSe, CdTe, CdSeS, CdSeTe, CdSTe, CdZnS, CdZnSe, CdZnTe, CdHgS, CdHgSe, CdHgTe, CdZnSeS, CdZnSeTe, CdZnSTe, CdHgSeS, CdHgSeTe, CdHgSTe, or any combination thereof.

17. An electronic device comprising the light-emitting device of claim 8.

18. The electronic device of claim 17,
further comprising a thin-film transistor,
wherein the thin-film transistor comprises a source electrode and a drain electrode, and
a first electrode of the light-emitting device is electrically connected to at least one selected from among the source electrode and the drain electrode of the thin-film transistor.

19. An electronic apparatus comprising the electronic device of claim 18.

20. The electronic apparatus of claim 19,
wherein the electronic apparatus is one selected from among a flat panel display, a curved display, a computer monitor, a medical monitor, a television, a billboard, an indoor light, an outdoor light, a signal light, a head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a microdisplay, a 3D display, a virtual reality display, an augmented reality display, a vehicle, a video wall comprising a plurality of displays tiled together, a theater screen, a stadium screen, a phototherapy device, and a signboard.
